(19) United States
(12) Patent Application Publication
(10) Pub. No.: US 2026/0223431 A1
(43) Pub. Date: Jul. 30, 2026

(54) BACKSIDE GATE CONTACTS AND METHODS OF FORMING THE SAME

(71) Applicants: Taiwan Semiconductor Manufacturing co., Ltd., Hsinchu (TW); TSMC Arizona Corporation, Phoenix, AZ (US)

(72) Inventors: Cheng-Yi Peng, Taipei City (TW); Tso-Hsuan Chen, Phoenix, AZ (US); Tsung-Chieh Hsiao, Shetou Township (TW); Chih-Lin Wang, Zhubei City (TW)

(21) Appl. No.: 19/226,661

(22) Filed: Jun. 3, 2025

Related U.S. Application Data
(60) Provisional application No. 63/751,433, filed on Jan. 30, 2025.
(60) Provisional application No. 63/760,368, filed on Feb. 19, 2025.

(51) Int. Cl. H10D 84/01; H10D 84/85

(52) U.S. Cl. CPC H10D 84/0186; H10D 84/851; H10D 84/853

(57) ABSTRACT

A method includes forming a transistor as a part of a wafer. The transistor includes a semiconductor channel, a gate stack comprising a gate dielectric over the semiconductor channel and a gate electrode over the gate dielectric, and a source/drain region aside of, and joined to, an end of the semiconductor channel. The method further comprises forming a source/drain contact plug over and electrically coupling to the source/drain region, and performing an etching process from a backside of the wafer to form a gate contact opening. The gate dielectric is etched-through, and the gate electrode is exposed to the gate contact opening. A backside gate contact plug is formed in the gate contact opening.

### PRIORITY CLAIM AND CROSS-REFERENCE

This application claims the benefit of the following provisionally filed U.S. Patent application: Application No. 63/760,368, filed on Feb. 19, 2025, and entitled “Backside Gate Contact,” and Application No. 63/751,433, filed on Jan. 30, 2025, and entitled “Backside Gate Contact and Methods of Forming,” which applications are hereby incorporated herein by reference.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (for example, transistors, diodes, resistors, capacitors, etc.) through continual reduction in minimum feature size, which allows more components to be integrated into a given area. As the minimum feature sizes are reduced, however, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A, 1B, 1C and 1D through FIGS. 11A, 11B, 11C and 11D illustrate the views in the formation of Fin Field-Effect Transistors (FinFETs) and contact plugs in accordance with some embodiments.

FIGS. 12A, 12B, 12C and 12D through FIGS. 22A, 22B, 22C and 22D illustrate the views in the formation of nanosheet transistors and contact plugs in accordance with some embodiments.

FIG. 23 illustrates a process flow for forming transistors and contact plugs in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Fin Field-Effect Transistor (FinFETs), nanosheet transistors, and the methods of forming the same are provided. In accordance with some embodiments of the present disclosure, transistors, which may be FinFETs or nanosheet transistors, are formed on a wafer. Source/drain contact plugs may be formed on a first side (such as front side) of the transistors. Gate contact plugs are formed on a second side (such as backside) of the transistors. By spreading the source/drain contact plugs and gate contact plugs to different sides of the transistors, the spacings between neighboring contact plugs are enlarged. Electrical shorting may be avoided, and leakage may be reduced.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

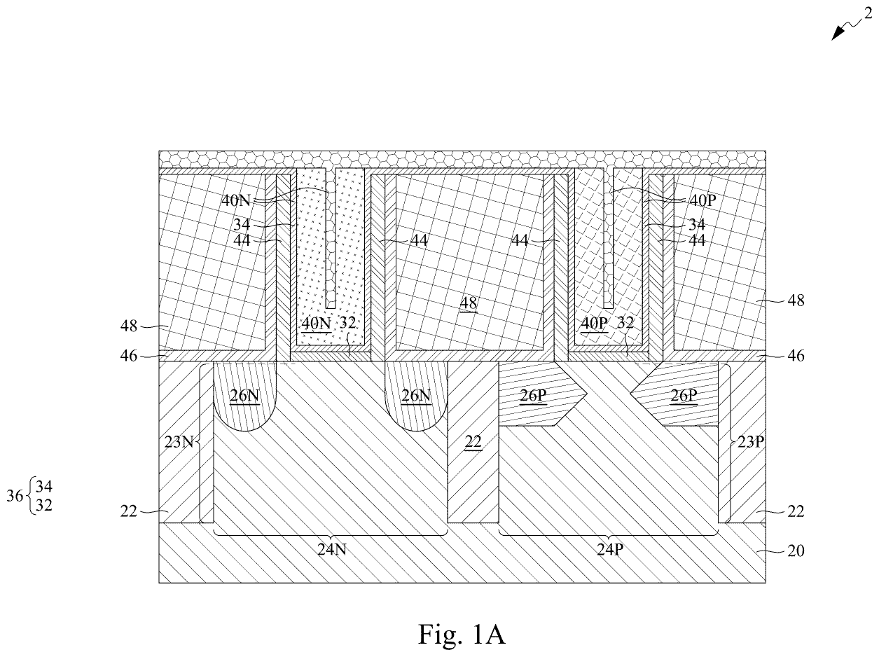

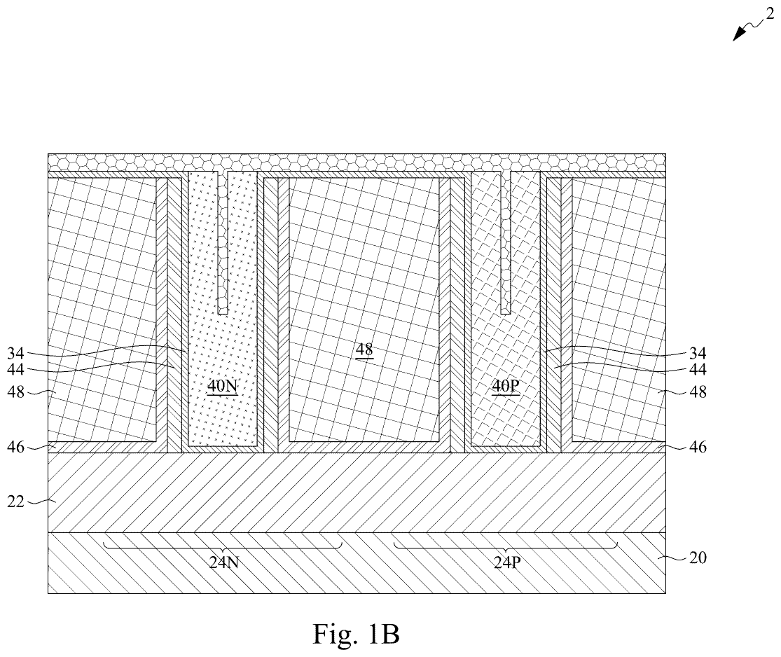

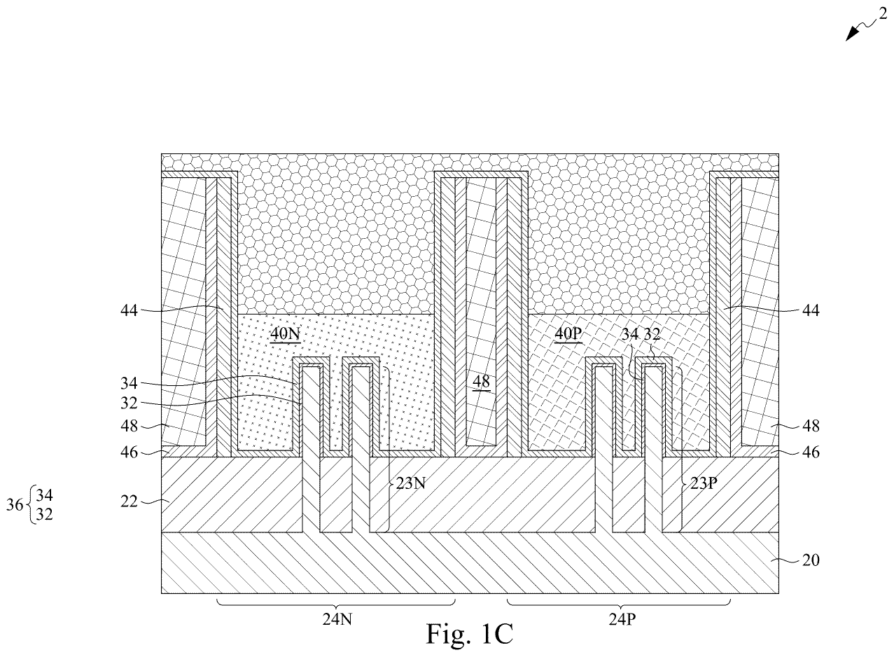

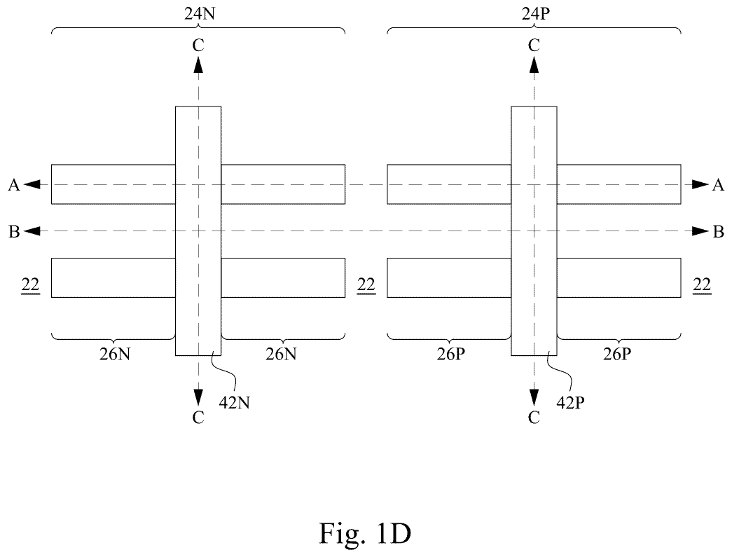

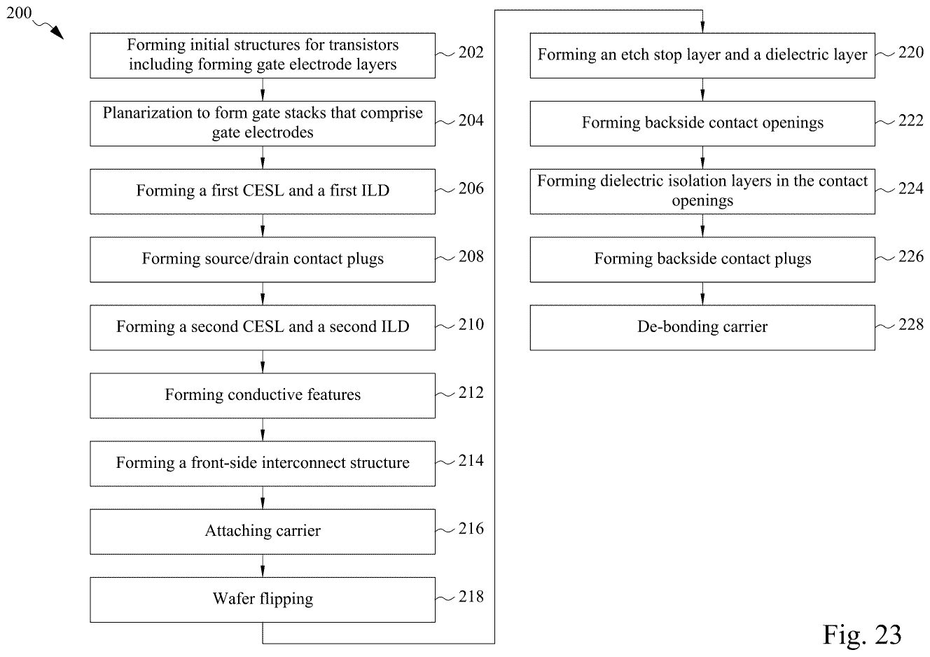

FIGS. 1A, 1B, 1C and 1D through FIGS. 11A, 11B, 11C and 11D illustrate the views in the formation of Fin Field-Effect Transistors (FinFETs) in accordance with some embodiments. The corresponding processes are also reflected schematically in the process flow shown in FIG. 23.

FIGS. 1A, 1B, 1C and 1D illustrate the cross-sectional views and a top view of the formation of an initial structure of FinFETs 24N and 24P (also referred to as transistors) in accordance with some embodiments. The respective process is illustrated as process 202 in the process flow 200 as shown in FIG. 23. In accordance with some embodiments, as shown in FIG. 1D, which illustrates a top view, n-type FinFET 24N (also referred to as an n-type transistor 24N or an NMOS 24N) and p-type FinFET 24P (also referred to as a p-type transistor 24P or a PMOS 24P) are formed. FIG. 1A illustrates the cross-sectional view obtained from cross-section A-A in FIG. 1D. FIG. 1B illustrates the cross-sectional view obtained from cross-section B-B in FIG. 1B. FIG. 1C illustrates the cross-sectional views obtained from cross-sections C-C in FIG. 1D. In subsequent Figures, the cross-sectional views of figures whose figure numbers include letters “A,” “B,” and “C” may also be obtained from the similar cross-sections as shown in FIG. 1D.

As shown in FIG. 1D, n-type FinFET 24N includes source/drain regions 26N and gate stack 42N. P-type FinFET 24P includes source/drain regions 26P and gate stack 42P. The cross-section shown in FIG. 1A cuts through the active regions, including channels and source/drain regions of the n-type FinFET 24N and p-type FinFET 24P.

As shown in FIG. 1A, wafer 2, which includes substrate 20, is provided. Substrate 20 may be a semiconductor substrate, such as a bulk semiconductor substrate, a semiconductor-on-insulator (SOI) substrate, or the like, which may be doped (e.g., with a p-type or an n-type dopant) or undoped. Other substrate structures such as a multilayered or a gradient substrates may also be used. In some embodiments, the semiconductor material of the substrate 20 may include silicon, germanium, carbon-doped silicon, a III-V compound semiconductor, or the like, or combinations thereof.

Shallow Trench Isolation (STI) regions 22 are formed over the bulk portion of substrate 20, which bulk portion is also referred to as a bulk substrate. Semiconductor fins 23N and 23P (also referred to as semiconductor strips) are formed between STI regions 22. In accordance with some embodiments, semiconductor fin 23N is of p-type and forms the p-type well region of the n-type FinFET 24N. Semiconductor fin 23P is of n-type and forms the n-type well region of the p-type FinFET 24P.

N-type FinFET 24N includes source/drain regions 26N, which are n-type regions. Source/drain regions 26N may comprise Si, SiC, or the like, and may be doped with an n-type dopant selected from phosphorous, arsenic, antimony, and combinations thereof. The layers for forming gate stack 42N are formed on the sidewalls and the top surfaces (refer to FIG. 1C) of semiconductor fins 23N. Gate spacers 44 are formed on the opposing sidewalls of portions of the gate stack layers 42N.

The formation of source/drain regions 26N may include etching semiconductor fins 23N to form recesses, and performing an epitaxy process to epitaxially grow semiconductor materials in the recesses. In an embodiment, source/drain regions 26N may have inner edges (that face channel regions) being substantially straight and vertical, and curved bottom surfaces.

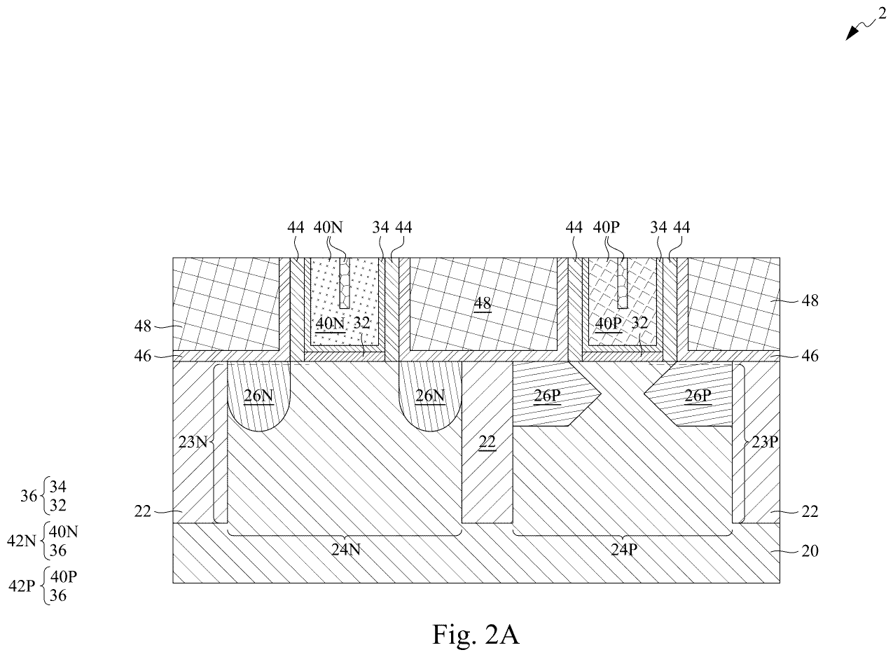

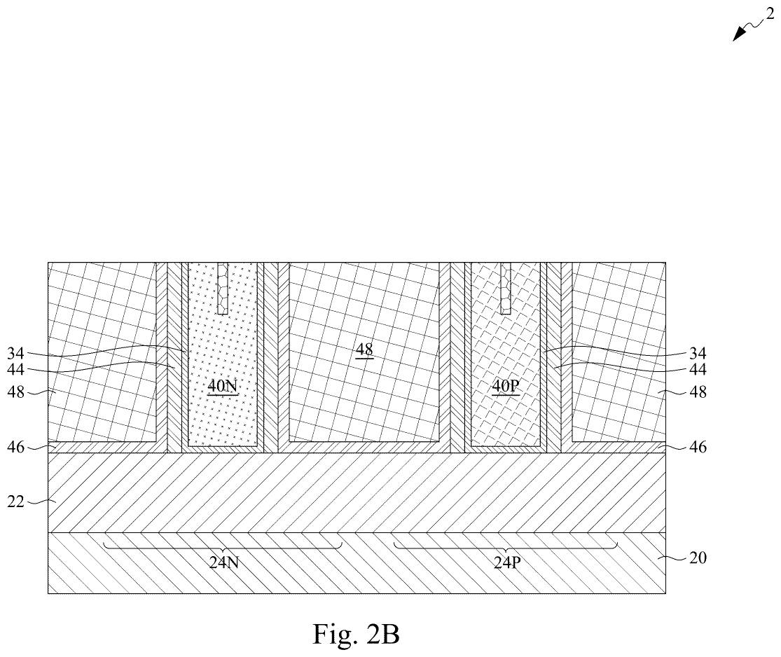

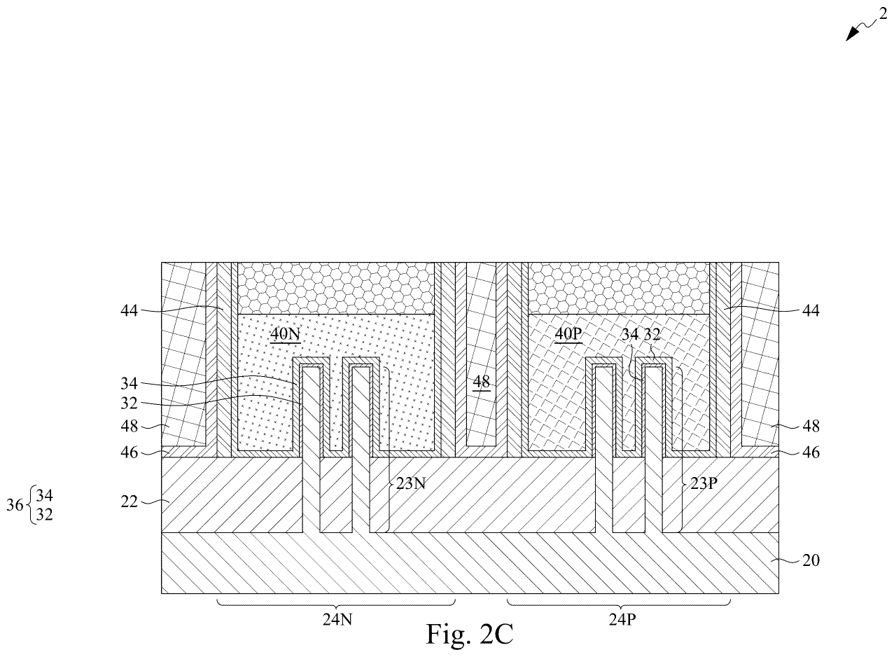

In accordance with some embodiments, as shown in FIG. 1A, the gate stack layers of the n-type FinFET 24N includes interfacial layer 32 and high-k dielectric layer 34, which collectively form gate dielectric 36. Gate electrode layers 40P are formed over gate dielectric 36. In accordance with some embodiments, the formation of the gate stack layers may include forming dummy gate stacks (not shown) between gate spacers 44, removing the dummy gate stacks, and forming the gate stack layers extending into the recesses. It is appreciated that while FIG. 1D illustrates gate stacks 42N and 42P, the formation of gate stack 42N and 42P are actually finished by the planarization process as shown in FIGS. 2A, 2B, and 2C.

Gate electrode layer(s) 40N may comprise a plurality of layers such as adhesion layers, work-function layers, capping layers, filling metals, and/or the like. The work-function layers in gate electrode layers 40N may have an n-type work function, which is relatively low, for example, lower than about 4.5 eV, and may comprise AlN, TiAlN, or the like. Alternatively, the work-function layers in gate electrode layers 40N may have a mid-gap work function, which may be around 4.5 eV to about 4.6 eV. The adhesion layer and capping layer may comprise TiN. The filling metal may comprise tungsten, cobalt, or the like.

P-type FinFET 24P includes source/drain regions 26P, which are p-type regions. Source/drain regions 26P may comprises Si, SiGe, or the like, and may be doped with a p-type dopant selected from boron, indium, and combinations thereof. Gate stack layers (including layers 32, 34 and 40P) are formed on the sidewalls and the top surfaces (refer to FIG. 1C) of semiconductor fins 23P. Gate spacers 44 are formed on the opposing sidewalls of gate stack 42P.

The formation of source/drain regions 26P may include etching semiconductor fins 23P to form recesses, and performing an epitaxy process to grow semiconductor materials in the recesses. In an embodiment, source/drain regions 26P may have inner edges (that face channel regions) formed as facets.

In accordance with some embodiments, as shown in FIG. 1A, the gate stack layers of the gate stack of the p-type FinFET 24P includes interfacial layer 32 and high-k dielectric layer 34, which collectively form gate dielectric 36. Gate electrode layers 40P are formed over gate dielectric 36. In accordance with some embodiments, the formation of the gate stack layers may include forming dummy gate stacks (not shown) between gate spacers 44, removing the dummy gate stacks to form recesses, and forming the gate stack layers extending into the recesses.

Gate electrode layer(s) 40P may comprise a plurality of layers such as adhesion layers, work-function layers, capping layers, filling metals, and/or the like. The work-function layers in gate electrode layers 40P may have a p-type work function, which is relatively high, for example, higher than about 4.6 eV. The corresponding material may include TiN. Alternatively, the work-function layers in gate electrode layers 40P may have a mid-gap work function, which may be around 4.5 eV to about 4.6 eV. The adhesion layer and capping layer may comprise TiN. The filling metal may comprise tungsten, cobalt, or the like.

Contact etch stop layer (CESL) 46 and Inter-layer dielectric (ILD) 48 are formed over the source/drain regions 26N and 26P. The CESL 46 may be formed of a dielectric material having a high etching selectivity from the etching of the ILD 48. For example, the CESL 46 may comprise silicon nitride, silicon oxide, silicon oxynitride, or the like, which may be formed by any suitable deposition process, such as CVD, ALD, or the like. The applicable dielectric material of the ILD 48 may include phospho-silicate glass (PSG), boro-silicate glass (BSG), boron-doped phospho-silicate glass (BPSG), undoped silicate glass (USG), silicon oxide, or the like.

The cross-section shown in FIG. 1B cuts through the STI regions (refer to the cross-section 1B-1B in FIG. 1D). Gate stacks 42N and 42P comprise some portions extending over the top surfaces of STI regions 22, which portions are separated from the underlying substrate 20, which is a bulk portion/substrate, by STI regions 22.

The cross-section shown in FIG. 1C cuts through gate stacks 42N and 42P and extends in the lengthwise directions of gate stacks 42N and 42P. It is noted that while in FIG. 1D, the cross-section C-C cutting through the gate stack 42N is not in the same cross-section as the cross-section C-C cutting through the gate stack 42P, the two cross-sections are illustrated in the same cross-sectional view as shown in FIG. 1C for clarity.

As shown in FIGS. 1A, 1B, and 1C, the deposited gate stack layers for forming gate stacks 42N and 42P may include some portions over the top surface of ILD 48. FIGS. 2A, 2B, and 2C illustrate a planarization process for removing excess portions of the gate stack layers. The respective process is illustrated as process 204 in the process flow 200 as shown in FIG. 23. In accordance with some embodiments, the planarization process may be performed through a Chemical Mechanical Polish (CMP) process or a mechanical polish process. The portions of the gate stack layers over ILD 48 are removed, exposing ILD 48. As a result of the planarization process, gate stacks 42N and 42P, which comprise gate electrodes 40N and 40P, respectively, are formed.

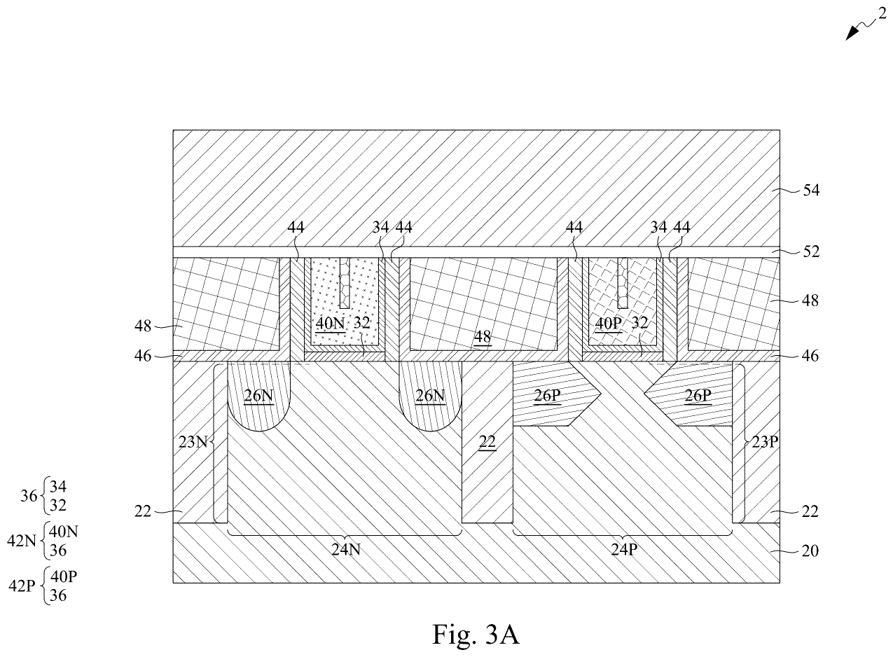

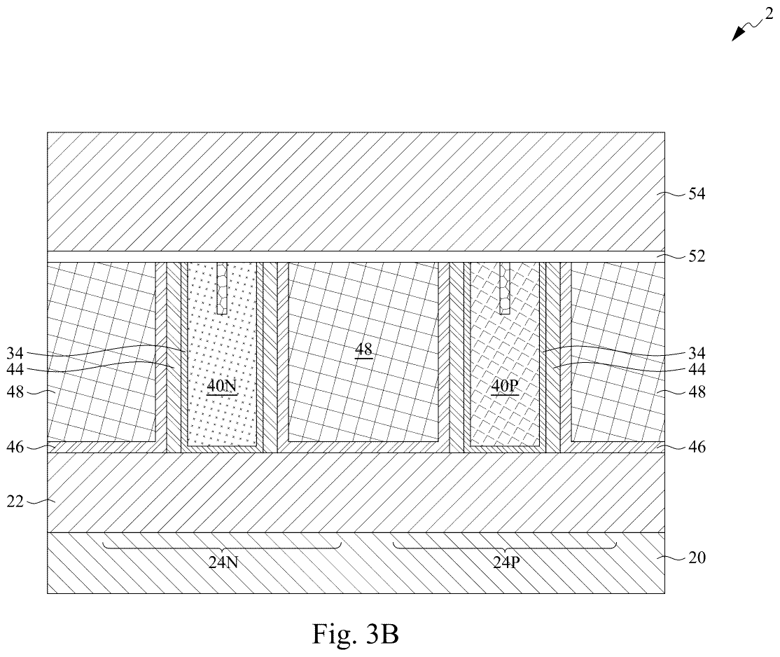

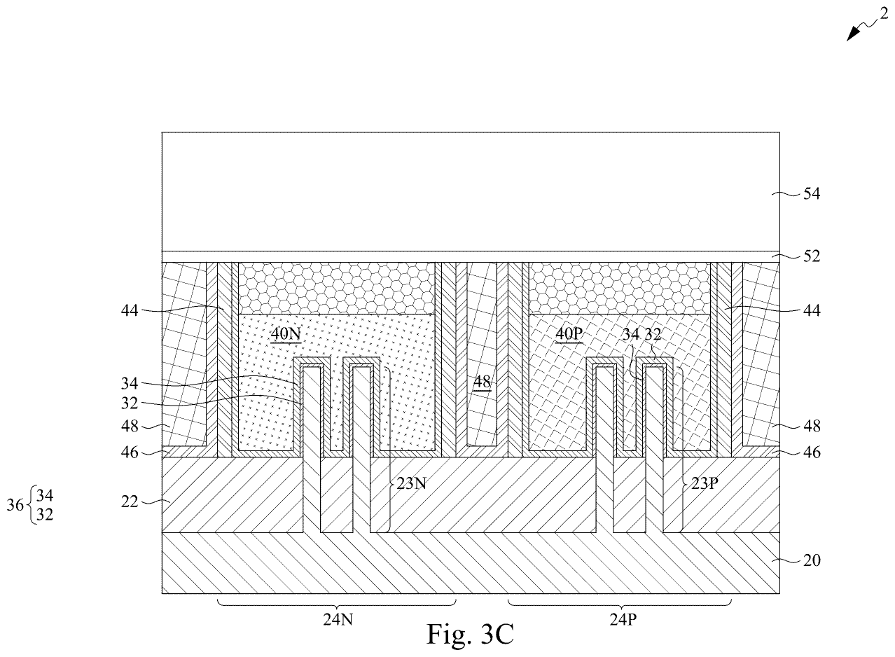

Referring to FIGS. 3A, 3B, and 3C, Etch Stop Layer (ESL) 52 and ILD 54 are formed over the source/drain regions 26N and 26P. The respective process is illustrated as process 206 in the process flow 200 as shown in FIG. 23. In accordance with some embodiments, the ESL 52 may comprise aluminum oxide, aluminum nitride, silicon oxycarbide, silicon nitride, silicon oxide, silicon oxynitride, or the like, or multilayers thereof, which may be formed by any suitable deposition process such as CVD, ALD, or the like. The applicable dielectric material of the ILD 54 may include silicon oxide, PSG, BSG, BPSG, USG, or the like.

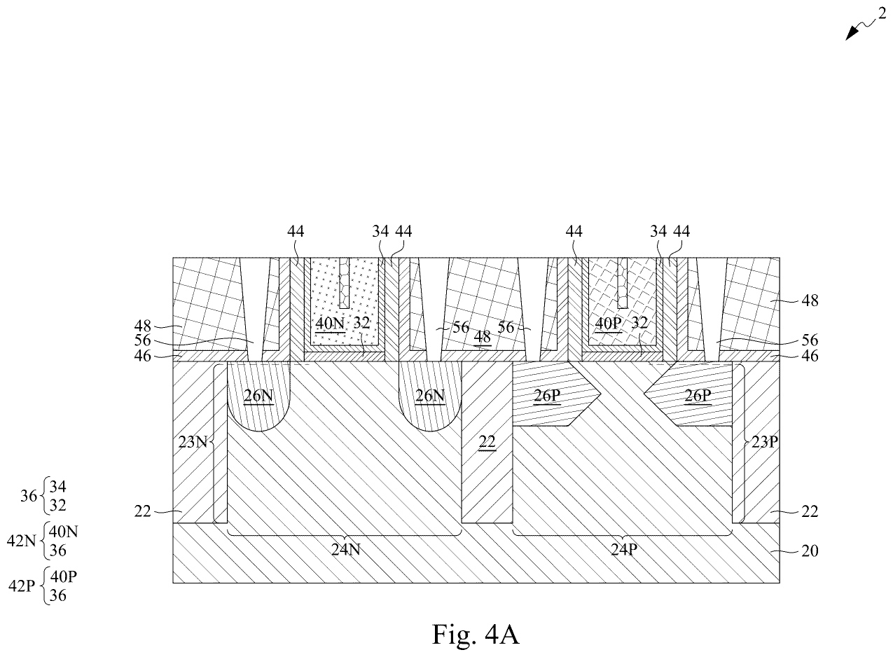

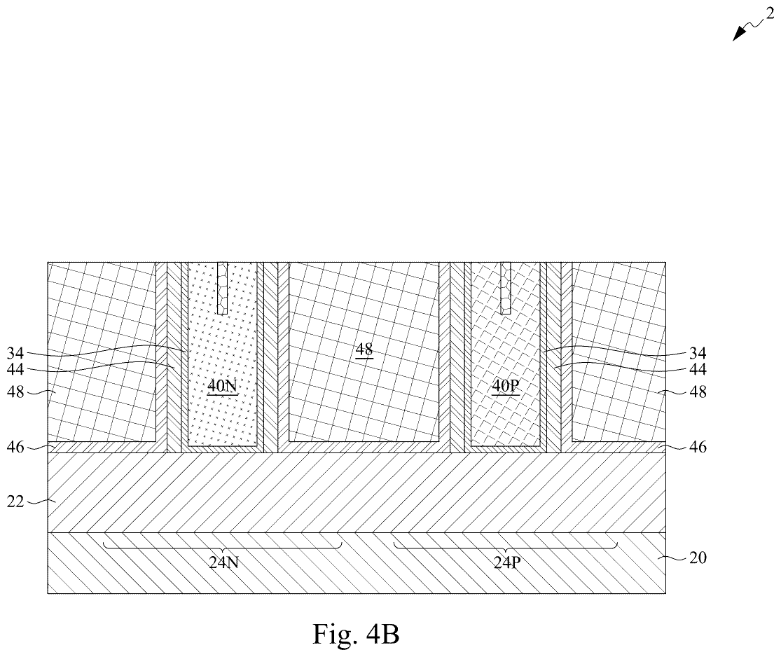

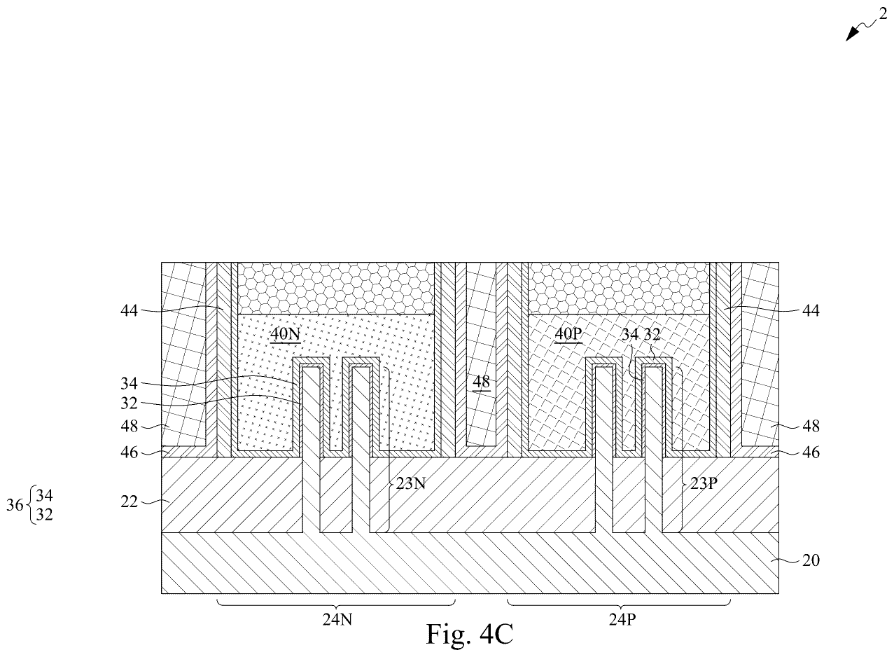

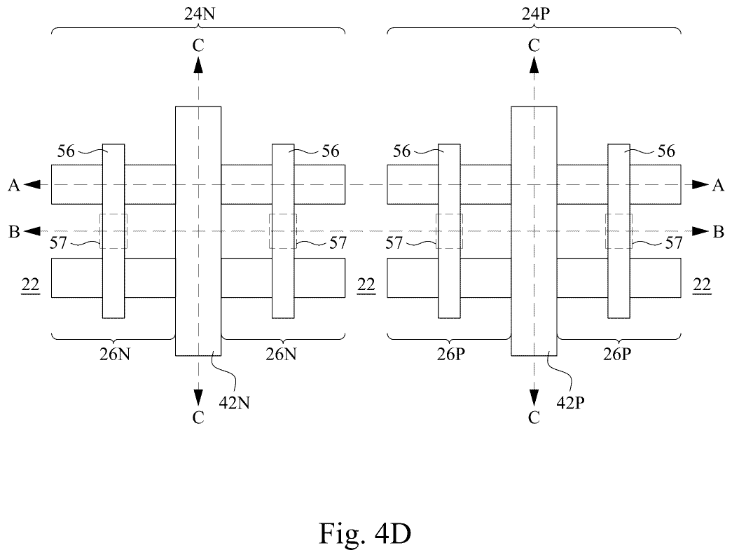

FIGS. 4A, 4B, and 4C and 4D illustrate the formation of source/drain contact plugs 56 in accordance with some embodiments. The respective process is illustrated as process 208 in the process flow 200 as shown in FIG. 23. In accordance with some embodiments, the formation processes include etching ILD 54, ESL 52, ILD 48, and CESL 46 to form contact openings, reveal source/drain regions 26N and 26P. Silicide layers (not shown) may be formed over the top surfaces of source/drain regions 26N and 26P through silicidation processes. Conductive materials such as TiN, tungsten, cobalt, or the like, or multi-layers thereof, may then be deposited to fill the contact openings.

In accordance with some embodiments, as shown in FIG. 4D, the source/drain contact plugs 56 over neighboring source/drain regions 26N (or 26P) may be interconnected. In accordance with alternative embodiments, the source/drain contact plugs 56 do not extend into regions 57 as in FIG. 4D, and FIG. 4B illustrates the corresponding structure.

A planarization process such as a CMP process or a mechanical polish process is then performed to remove the excess portions of the deposited materials, leaving source/drain contact plugs 56. In accordance with some embodiments, as shown in FIGS. 4A, 4B, and 4C, the planarization process may be performed until ILD 54 and ESL 52 are removed, and ILD 48 is exposed. The remaining portions of the conductive materials include source/drain contact plugs 56.

In accordance with alternative embodiments, the planarization process may be performed to remove the excess portions of the conductive materials over ILD 54, and the ILD 54 and ESL 52 are left in the final structure. In accordance with these embodiments, ESL 52 has a bottom surface contacting the top surfaces of gate stacks 42N and 42P. There are no gate contact plugs over and contacting the top surfaces of gate electrodes 40N and 40P.

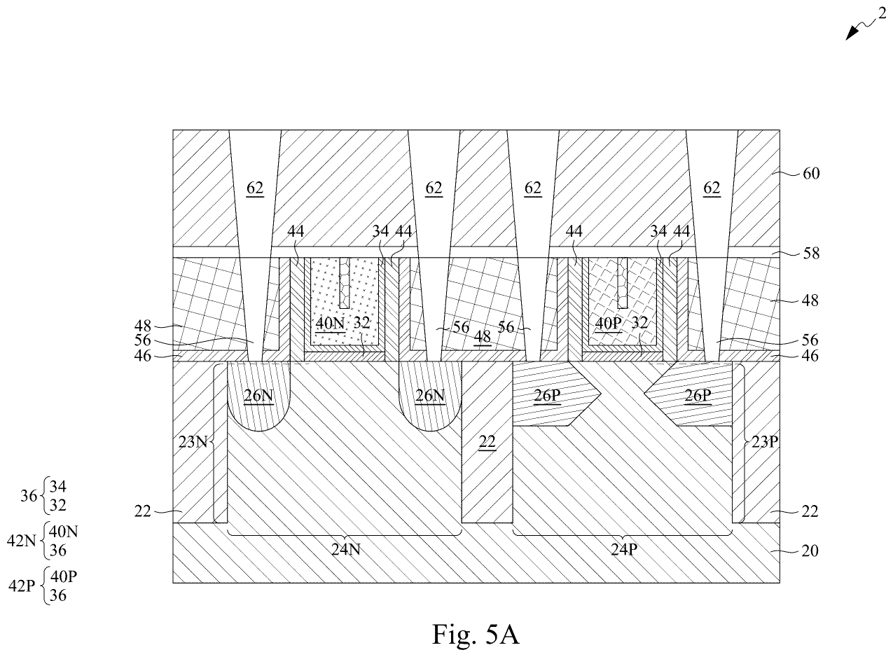

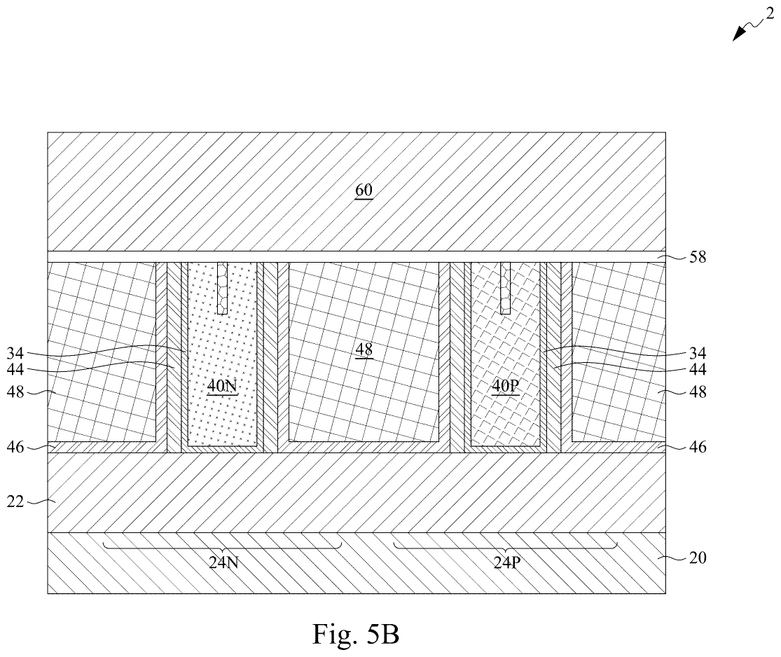

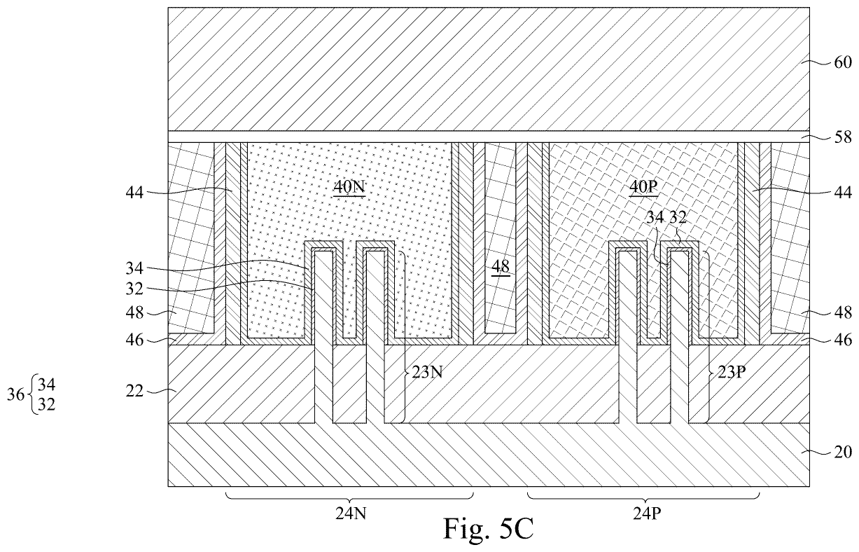

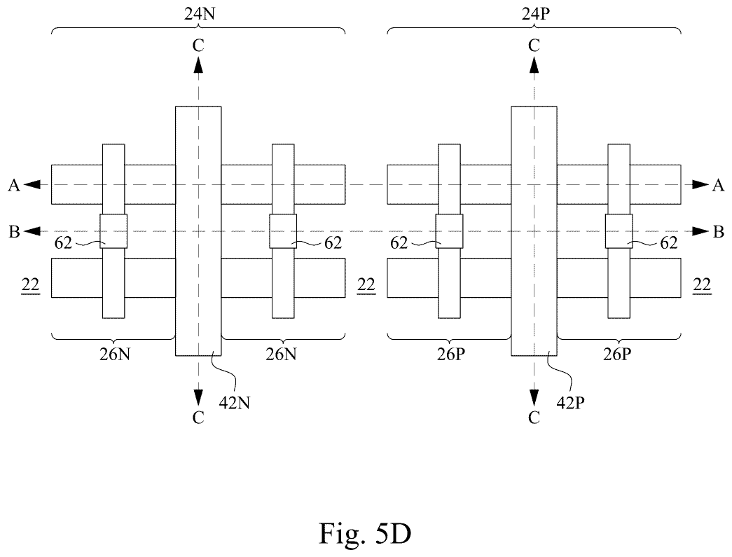

FIGS. 5A, 5B, 5C, and 5D illustrate the formation of ESL 58, ILD 60, and conductive features 62 in accordance with some embodiments. The respective processes are illustrated as process 210 and 212 in the process flow 200 as shown in FIG. 23. In accordance with some embodiments, ESL 58 may comprise aluminum oxide, aluminum nitride, silicon oxycarbide, or the like, or multilayers thereof, which may be formed by any suitable deposition process, such as CVD, ALD, or the like. The applicable dielectric material of the ILD 60 may include silicon oxide, PSG, BSG, BPSG, USG, or the like.

Next, conductive features 62 are formed in ILD 60 and ESL 58, and are over and in contact with source/drain contact plugs 56. In accordance with some embodiments, conductive features 62 are formed through a single damascene process, as shown in 5A, 5B, 5C. In accordance with alternative embodiments, a dual damascene may be performed to form overlying conductive features. The illustrated conductive features 62 may be the vias of the dual damascene structure, and the metal line portions of the dual damascene structure are not illustrated. Conductive features 62 may comprise TiN, copper, tungsten, cobalt, and/or the like.

In accordance with these embodiments, ESL 58 has a bottom surface contacting the top surfaces of gate stacks 42N and 42P. In the final structure, there may be no gate contact plugs over and contacting the top surfaces of gate electrodes 40N and 40P. Gate electrodes 40N and 40P are electrically connected to other features through backside contact plugs, which are formed in subsequent processes.

FIG. 5D illustrates a top view of the structure. It is appreciated that FIG. 5D illustrates that conductive features 62 are actually not in the cross-section A-A as shown in FIG. 5A, and conductive features 62 are shown in FIG. 5A in an alternative embodiment.

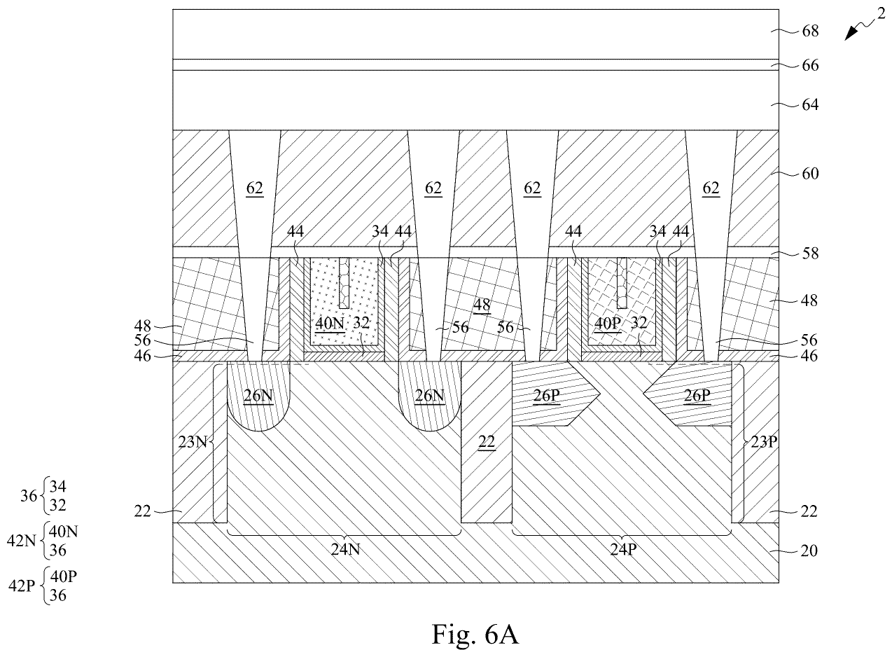

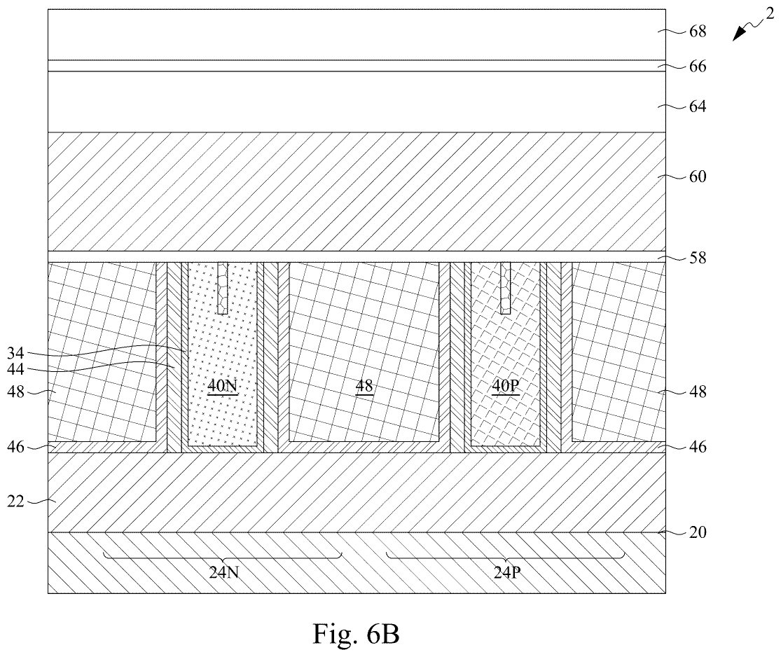

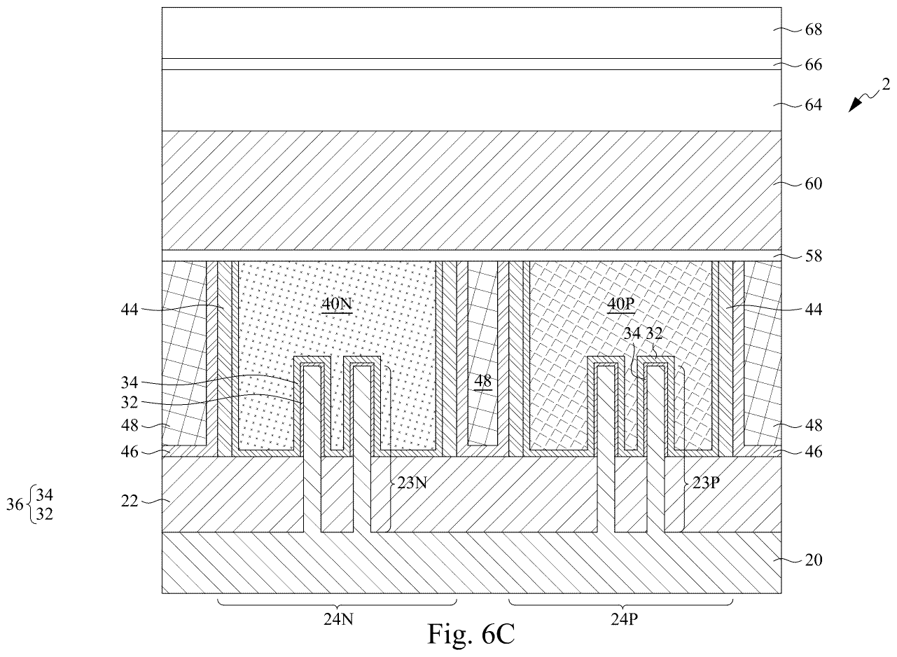

Referring to FIGS. 6A, 6B, and 6C, a (front-side) interconnect structure 64 is formed over conductive features 62 and ILD 60. The respective process is illustrated as process 214 in the process flow 200 as shown in FIG. 23. In accordance with some embodiments, upper interconnect structure 64 comprises metal line, vias, metal pads (such as AlCu pads), passivation layers, polymer layers, metal pillars, solder regions, and/or the like. The details of the upper interconnect structure 64 are not illustrated.

FIGS. 6A, 6B, and 6C further illustrate the attachment of carrier 68 to wafer 2. The respective process is illustrated as process 216 in the process flow 200 as shown in FIG. 23. In accordance with some embodiments, carrier 68 is attached to wafer 2 through release film 66. Carrier 68 may be a glass carrier, an organic carrier, or the like. Release film 66 may be formed of a polymer-based material and/or an epoxy-based thermal-release material (such as a Light-To-Heat-Conversion (LTHC) material), which is capable of being decomposed under radiation such as a laser beam, so that carrier 68 may be de-bonded from wafer 2 in a subsequent process. In accordance with some embodiments, release film 66 is applied on carrier 68 through spin-on coating or adhesion.

In accordance with alternative embodiments, a silicon-containing dielectric layer (not shown) may be formed as a top surface feature of interconnect structure 64. Correspondingly, carrier 68 may include a silicon wafer and a silicon-containing dielectric layer formed on the silicon wafer. The silicon-containing dielectric layers of carrier 68 and interconnect structure 64 may include SiO, SiN, SiC, SiOC, SiON, SiOCN, or the like. The silicon-containing dielectric layer of carrier 68 may be bonded to the silicon-containing dielectric layer of interconnect structure 64 through fusion bonding. After the bonding, the silicon wafer may be thinned, or not thinned.

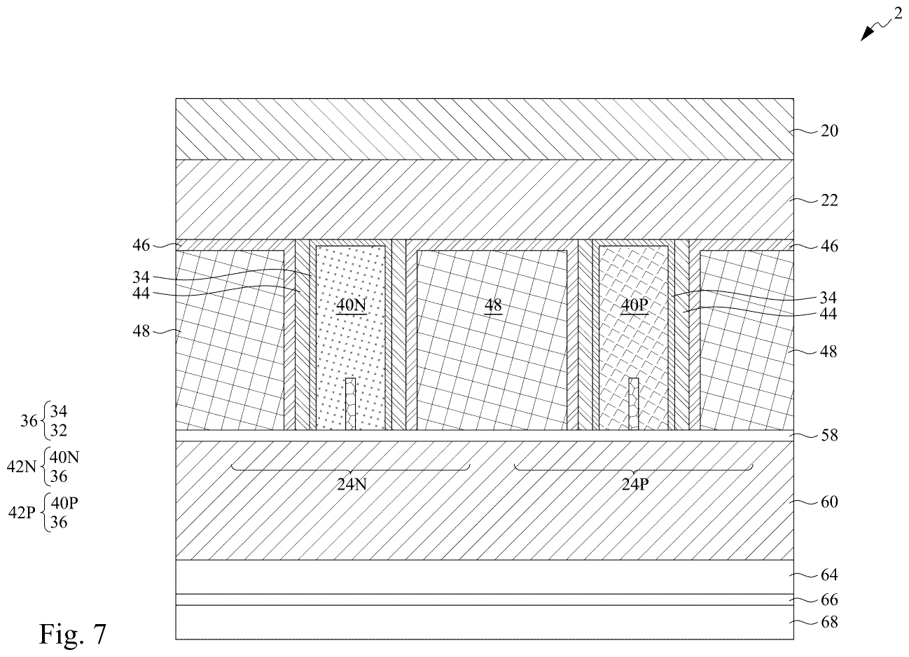

Next, the bonded structure including carrier 68 and wafer 2 is flipped upside down. The respective process is illustrated as process 218 in the process flow 200 as shown in FIG. 23. FIG. 7 illustrates the flipped structure as shown in FIG. 6B, wherein substrate 20 faces up.

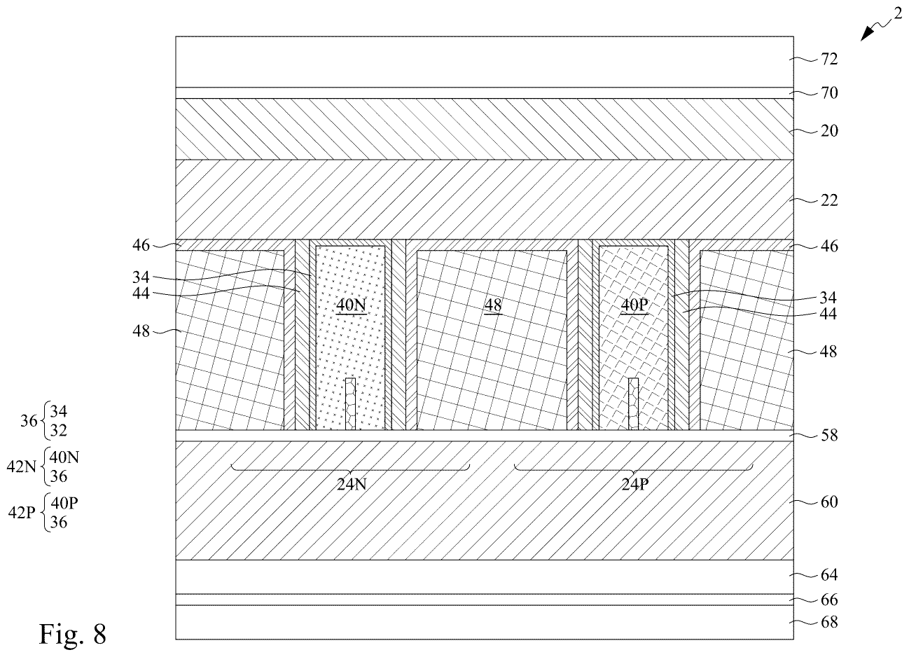

Referring to FIG. 8, etch stop layer (ESL) 70 and dielectric layer 72 are formed. The respective process is illustrated as process 220 in the process flow 200 as shown in FIG. 23. In accordance with some embodiments, etch stop layer 70 and dielectric layer 72 are sacrificial layers that are removed in subsequent processes. In accordance with alternative embodiments, etch stop layer 70 and dielectric layer 72 are left in the final structure.

In accordance with some embodiments, etch stop layer 70 may comprise aluminum oxide, aluminum nitride, silicon oxy-carbide, silicon oxynitride, multi-layers thereof, or the like, which may be formed by any suitable deposition process, such as CVD, ALD, or the like. The applicable dielectric material of the dielectric layer 72 may include silicon oxide, silicon nitride, silicon oxynitride, silicon oxy-carbo-nitride, silicon carbide, or the like.

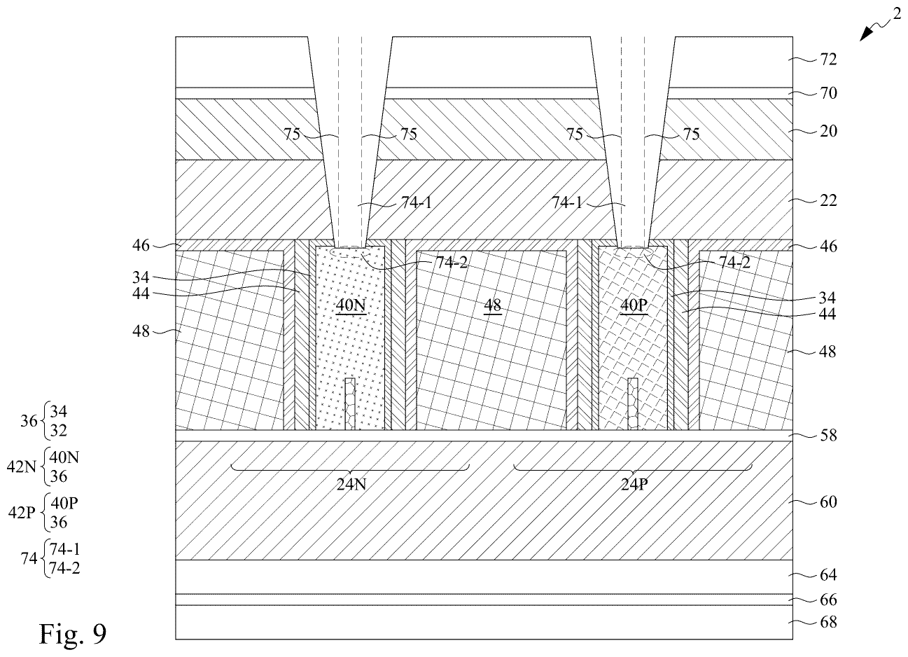

FIG. 9 illustrates the etching process to form backside contact openings 74. The respective process is illustrated as process 222 in the process flow 200 as shown in FIG. 23. The formation of backside contact openings 74 may include a plurality of etching processes, which are mainly anisotropic. In the etching process, dielectric layer 72, etch stop layer 70, substrate 20, STI regions 22, interfacial layer 32, and high-k dielectric layer 34 are etched-through, so that gate electrodes 40N and 40P are exposed.

In accordance with some embodiments, as shown in FIG. 9, contact openings 74 are formed as being tapered (with funnel shapes). This may be achieved by reducing the bias power in the etching process. Making contact openings 74 to have funnel shapes makes the subsequent filling of contact openings 74 easier, and the resistance of the resulting backside contact plugs may be reduced. It is appreciated that since the source/drain contact plugs are formed on the front side of transistors 24N and 24P, the pitch between gate contact plugs (to be formed in contact openings 74) from their neighboring conductive features is increased. This allows for the backside gate contact plugs to be formed as being more tapered without the concern of incurring increased risk of electrical shorting and leakage.

In accordance with alternative embodiments, contact openings 74 are formed as being straight and vertical. Dashed lines 75 illustrate the sidewall of dielectric layer 72, etch stop layer 70, substrate 20, and STI regions 22 when contact openings 74 are straight and vertical.

In accordance with some embodiments, contact openings 74 comprise upper portions 74-1 and lower portions 74-2. The lower portions 74-2 are also referred to as the expansion portions of contact openings 74. In accordance with some embodiments, the lower portions 74-2 are in gate electrodes 40P and 40N, while the sidewalls of interfacial layers 32 and high-k dielectric layers 34 are continuously connected to the sidewalls of STI regions 22 to form straight edges.

For example, the interfacial layers 32 and high-k dielectric layers 34 may be etched through an anisotropic etching process (through dry etch), followed by the etching of gate electrodes 40N and 40P through an isotropic etching (dry or wet). The etching of gate electrodes 40N and 40P may be performed using a chemical that does not attach interfacial layers 32 and high-k dielectric layers 34. Accordingly, expansion portions 74-2 are formed in gate electrodes 40N and 40P, and laterally expand beyond the respective edges of the overlying upper portions 74-2.

In accordance with alternative embodiments, expansion portions 74-2 also extend into interfacial layers 32 and high-k dielectric layers 34. For example, interfacial layers 32 and high-k dielectric layers 34 may be etched-through using an isotropic etching process (wet or dry). The etching of gate electrodes 40N and 40P may also be performed using an etching chemical (gas or chemical solution) that also etches interfacial layers 32 and high-k dielectric layers 34, but does not etch STI regions 22, substrate 20, ESL 70, and dielectric layer 72.

In accordance with alternative embodiments, there is no over-etching of gate electrodes 40N and 40P. Accordingly, the etching of interfacial layers 32 and high-k dielectric layers 34 may be performed using etching chemicals that do not attack gate electrodes 40N and 40P. The expansion portions 74-2 thus are not formed.

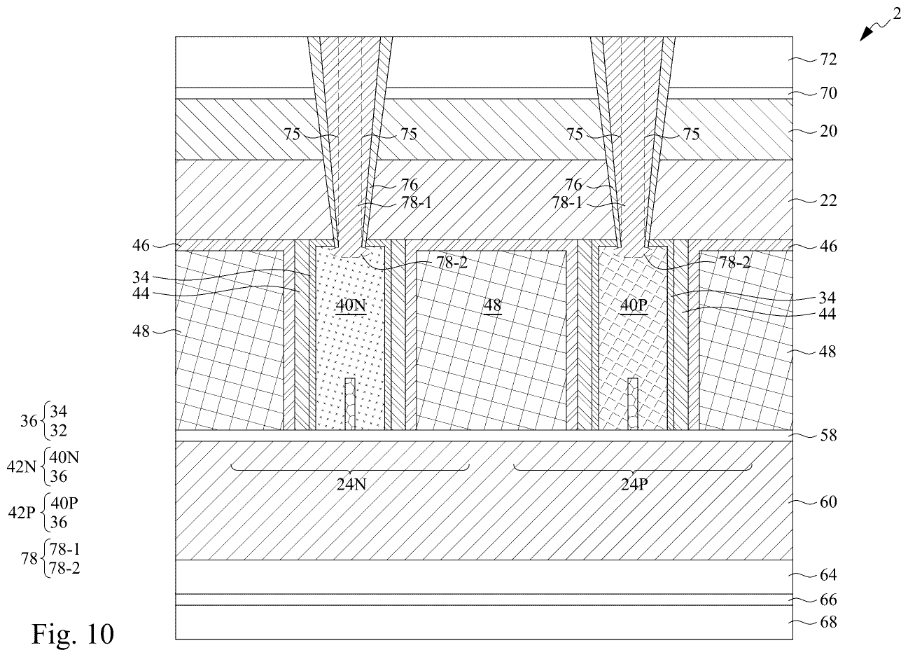

Referring to FIG. 10, dielectric isolation layers (dielectric liners) 76 are formed. The respective process is illustrated as process 224 in the process flow 200 as shown in FIG. 23. The formation process may include deposition a dielectric layer through a conformal deposition process such as ALD, CVD, or the like, and performing an anisotropic etching process to remove horizontal portions of the dielectric layer, so that gate electrodes 40N and 40P are exposed.

Next, a conductive material such as tungsten, cobalt, TiN, copper, or the like, or multi-layers thereof is formed/deposited (such as plated) to fill contact openings 74. A planarization process such as a CMP process or a mechanical grinding process may then be formed to remove excess portions of the deposited conductive material, leaving backside gate contact plugs 78. The respective process is illustrated as process 226 in the process flow 200 as shown in FIG. 23. As may be realized from FIG. 10, forming backside gate contact plugs 78 on an opposite side of transistors 24N and 24P results in the significant reduction of the spacing between neighboring contact plugs.

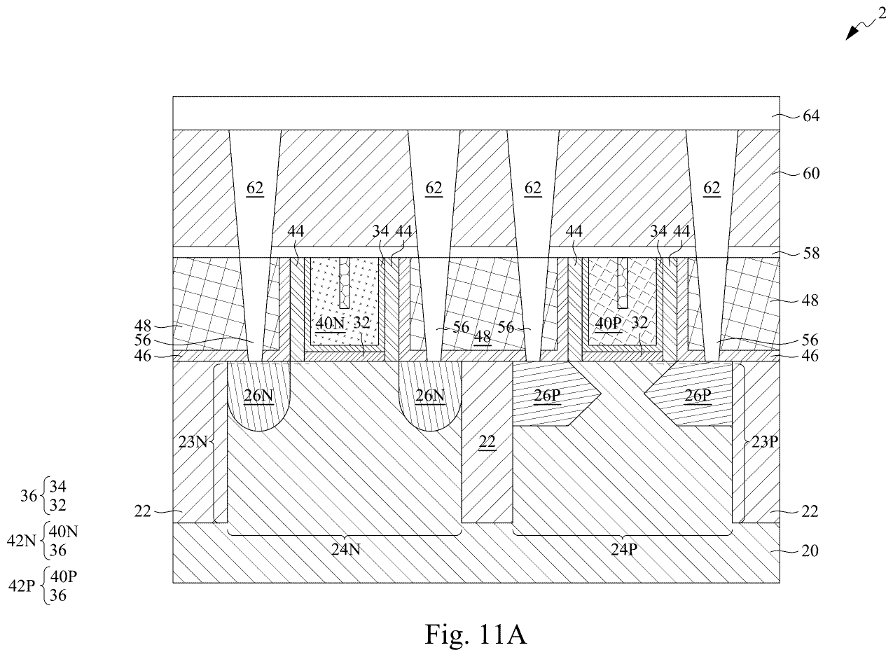

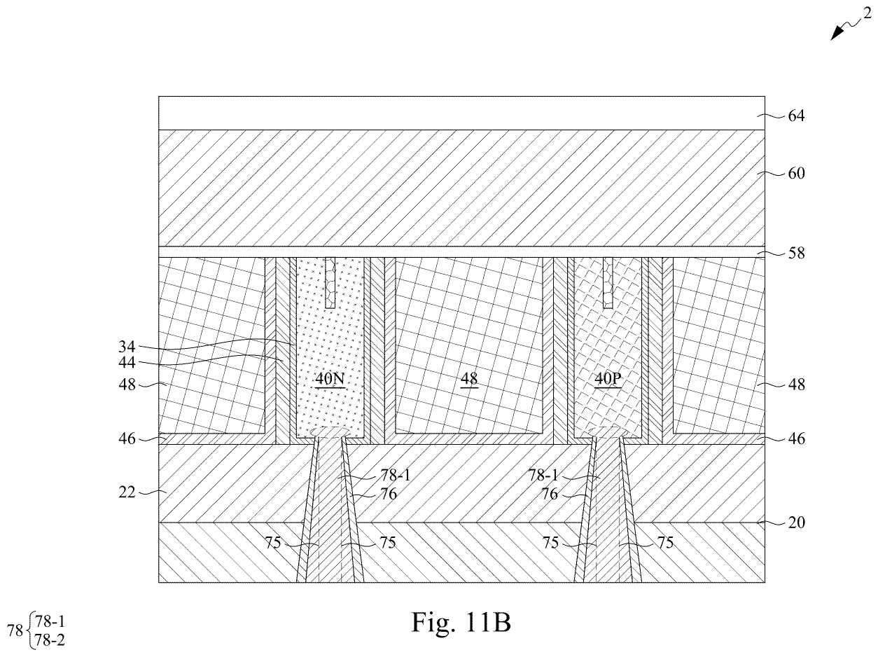

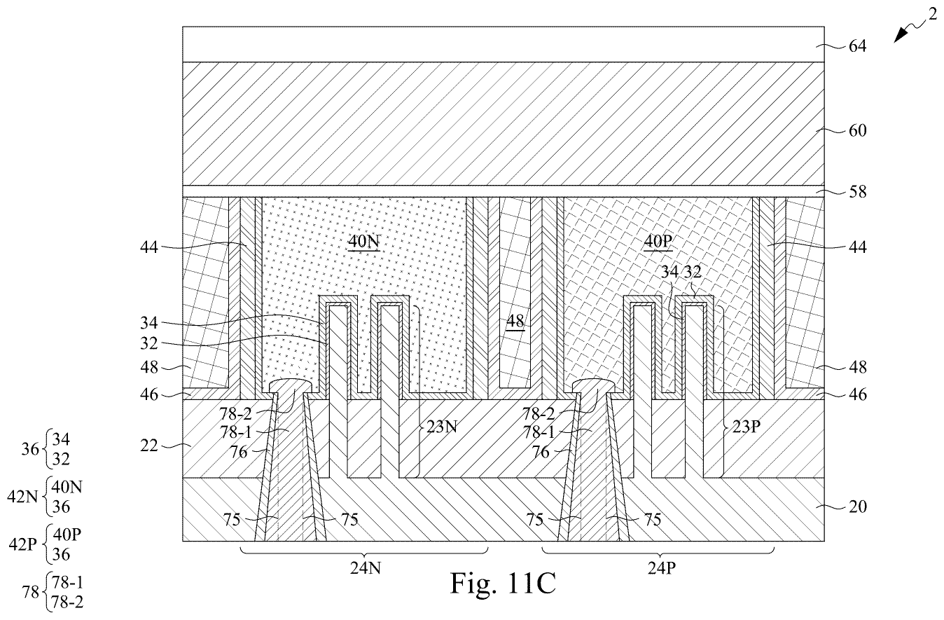

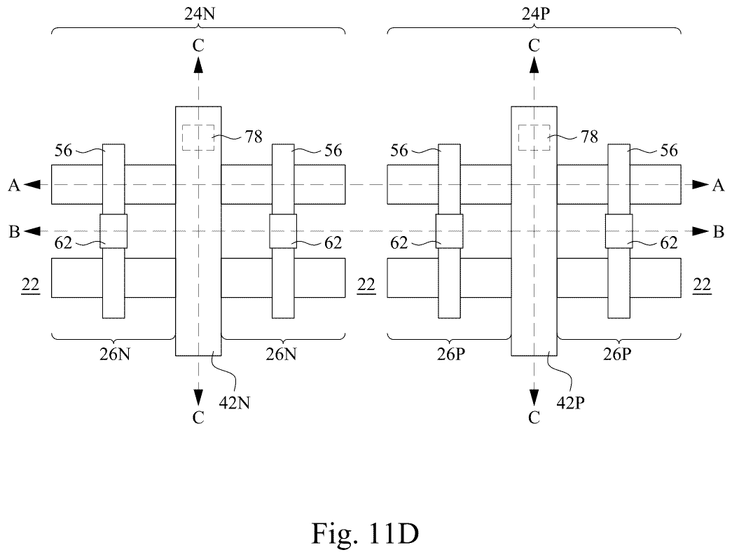

In accordance with some embodiments, as shown in FIG. 10, the planarization process may be performed to remove the excess portions of the conductive materials over dielectric layer 72, and the dielectric layer 72 is left in the final structure. In accordance with alternative embodiments, as shown in an example embodiment in FIGS. 11B and 11C, dielectric layer 72 and etch stop layer 70 may be sacrificial layers, and may be removed during the planarization process for forming backside contact plugs 78.

In accordance with some embodiments, backside contact plugs 78 include portions 78-1 that have straight edges, and expansion portions 78-2 in gate electrodes 42P and 42N. Expansion portions 78-2 may or may not extend into interfacial layers 32 and high-k dielectric layers 34. In accordance with alternative embodiments, expansion portions 78-2 are not formed. Accordingly, expansion portions 78-2 are illustrated as being dashed to indicate that the expansion portions 78-2 may or may not be formed.

In subsequent processes, more conductive features (not shown) such as metal lines and vias may be formed on the backside of transistors 24N and 24P, and to electrically connect to backside contact plugs 78. Carrier 68 may then be de-bonded from wafer 2. The respective process is illustrated as process 228 in the process flow 200 as shown in FIG. 23. In accordance with some embodiments in which carrier 68 comprises a glass carrier, a laser beam may be projected and penetrate through carrier 68 to decompose release film 66, so that wafer 2 is released from carrier 68.

FIGS. 11A, 11B, 11C, and 11D illustrate wafer 2 after the de-bonding of carrier 68. FIGS. 11A, 11B, and 11C illustrates the upside-down flipped structure as shown in FIG. 10. In FIGS. 11B and 11C, backside contact plugs 78 are formed to penetrate through substrate 20 and STI regions 22. FIG. 11C illustrates that backside contact plugs 78 may be aside of semiconductor fins 23N and 23P.

FIG. 11D illustrates the top view of backside contact plugs 78 in accordance with some embodiments. Since backside contact plugs 78 are on the backside of wafer 2, backside contact plugs 78 are illustrated as being dashed.

In accordance with some embodiments, the edges of the portions 78-1 of backside contact plugs 78 are straight and vertical, and the edges are shown using dashed lines 75. In accordance with some embodiments, the edges of the portions 78-1 of contact plugs 78 are straight and slanted, and the backside contact plugs 78 have funnel shapes.

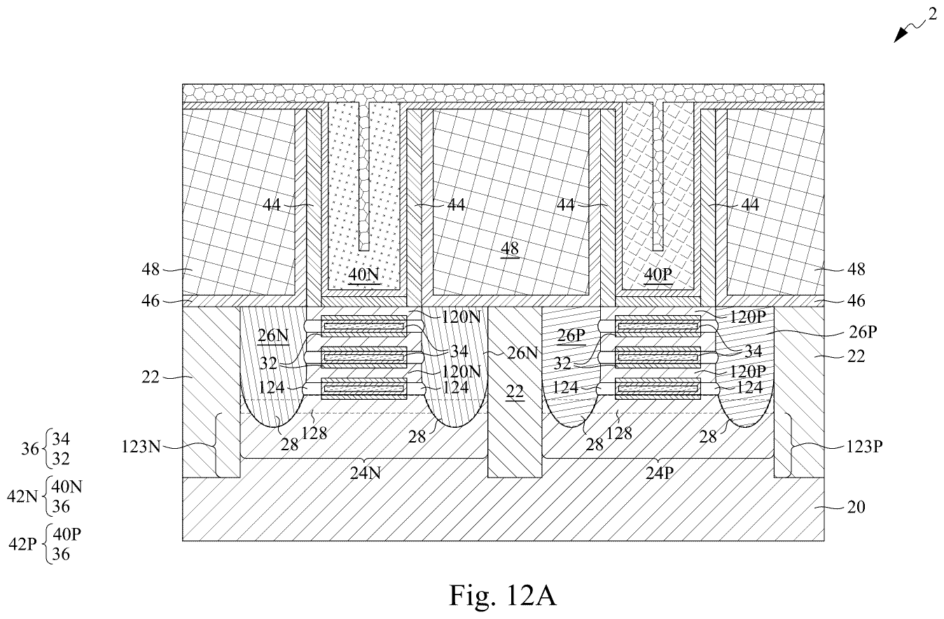

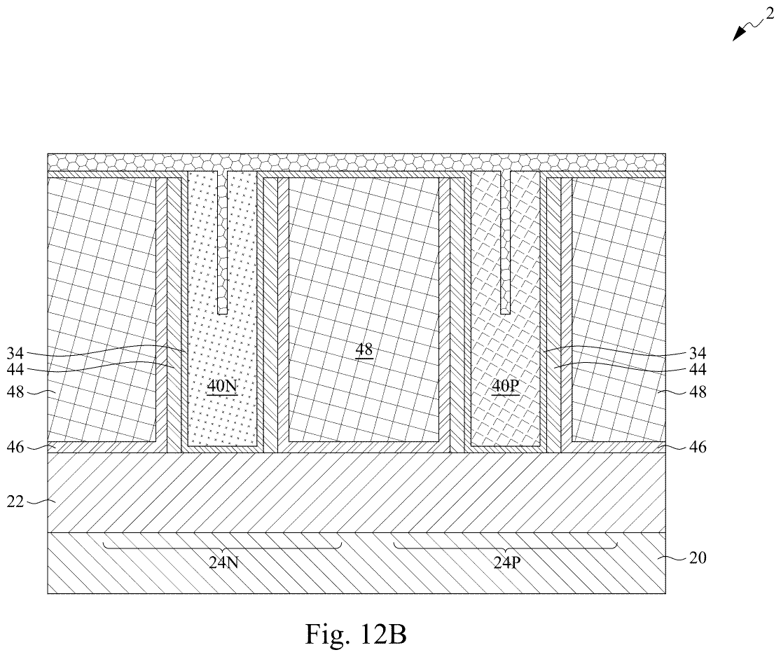

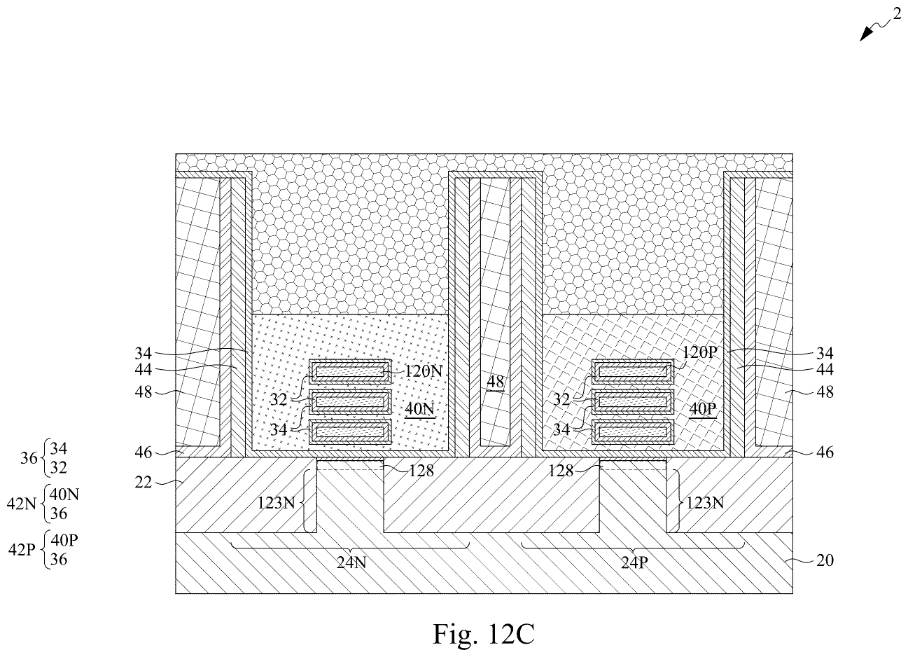

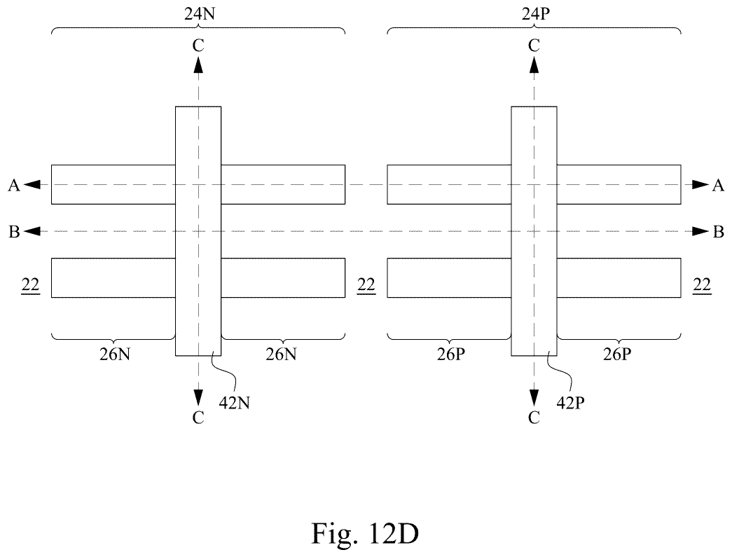

FIGS. 12A, 12B, 12C, and 12D through FIGS. 22A, 22B, 22C, and 22D illustrate the cross-sectional views of intermediate stages in the formation of nanosheet transistors in accordance with some embodiments of the present disclosure. These embodiments are similar to the preceding embodiments, except that instead of forming backside gate contact plugs for FinFETs, the backside gate contact plugs are formed on the backside of nanosheet transistors.

Unless specified otherwise, the materials, the structures, and the formation processes of the components in these embodiments are essentially the same as the like components denoted by like reference numerals in the preceding embodiments. The details regarding the materials, the structures, and the formation processes provided in each of the embodiments throughout the description may be applied to any other embodiment whenever applicable.

Referring to FIGS. 12A, 12B, 12C, and 12D, parts of n-type transistor 24N and p-type transistor 24P have been formed. FIGS. 12A, 12B, 12C also illustrate the cross-sections A-A, B-B, and C-C, respectively, in FIG. 12D. The formed portions include source/drain regions 26N and 26P, gate spacers 44, interfacial layers 32, high-k dielectric layers 34, and gate electrode layers 40N and 40P. STI regions 22 separate n-type transistor 24N from p-type transistor 24P. The channel regions of n-type transistor 24N include a plurality of semiconductor nanostructures 120N, which are semiconductor layers (nanosheets), and may be formed of or comprise silicon. Nanostructures 120N are of p-type. The channel regions of p-type transistor 24P include a plurality of nanostructures 120P, which are semiconductor layers (nanosheets), and may be formed of or comprise silicon. Nanostructures 120P are of N-type.

Interfacial layers 32, high-k dielectric layers 34, and gate electrode layers 40N comprise portions between nanostructures 120N. Interfacial layers 32, high-k dielectric layers 34, and gate electrode layers 40P comprise portions between nanostructures 120P. Inner spacers 124, which are dielectric regions, are formed on opposing ends of the gate stacks that are between nanostructures 120N and 120P.

The portion of the substrate 20 between neighboring STI regions 22 and underlying nanostructures 120N is referred to as semiconductor strip 123N. The portion of the substrate 20 between neighboring STI regions 22 and underlying nanostructures 120P is referred to as semiconductor strip 123P.

In accordance with some embodiments, source/drain regions 26N and 26P have bottom surfaces contacting semiconductor strips 123N and 123P, respectively. In accordance with alternative embodiments, dielectric regions 28 may be formed underlying source/drain regions 26N and 26P, and separate source/drain regions 26N and 26P from the underlying semiconductor strips 123N and 123P, respectively. Accordingly, dielectric regions 28 are illustrated as being dashed to indicate that these regions may be, or may not be, formed. CESL 46 and ILD 48 are also formed.

In accordance with some embodiments, dielectric layers 128 are formed directly underlying nanostructures 120N and 120P and overlying semiconductor strips 123N and 123P. The formation of dielectric layers 128 may include depositing or oxidizing the substrate 20, following by bonding a plurality of semiconductor layers over the dielectric layers 128. The plurality of semiconductor layers may include alternating silicon layers (nanostructures 120N and 120P) and silicon germanium layers, and the transistors 24N and 24P are formed based on the respective wafer including the bonded structure.

Dielectric layer 128 may comprise silicon oxide, silicon nitride, silicon oxynitride, silicon oxy-carbo-nitride, or the like. In the formation of source/drain regions 26N and 26P, etching processes may be performed. The etching process may be stopped on the top surfaces of dielectric layer 128. Accordingly, the source/drain regions 26N and 26P may contact the top surface of dielectric layer 128, which extends to opposing STI regions 26. Alternatively, in the etching processes for forming source/drain recesses, dielectric layers 128 may be etched-through, and the edges of the dielectric layers 128 are in contact with the edges of the resulting source/drain regions 26N and 26P, or the edges of dielectric regions 28, when formed.

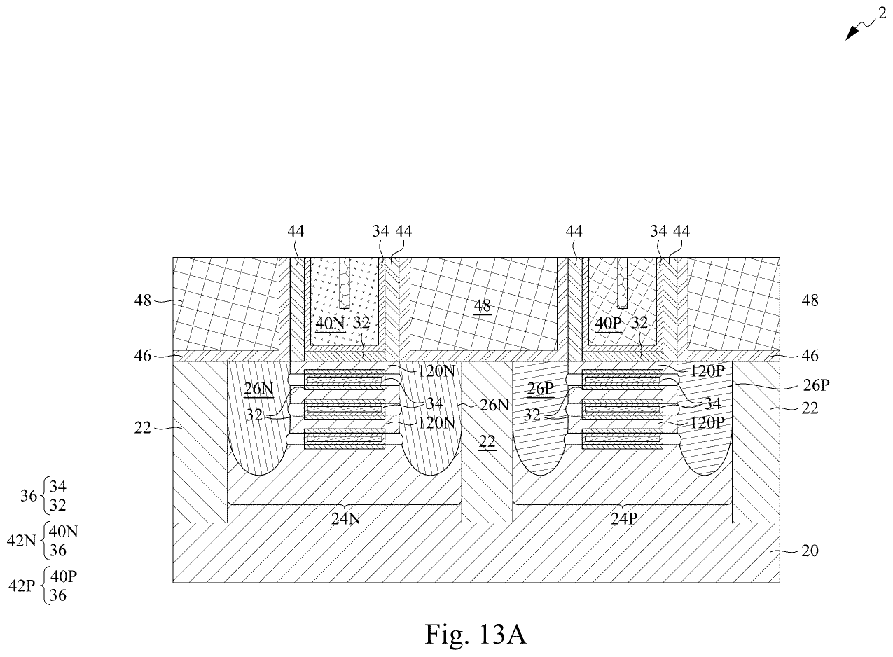

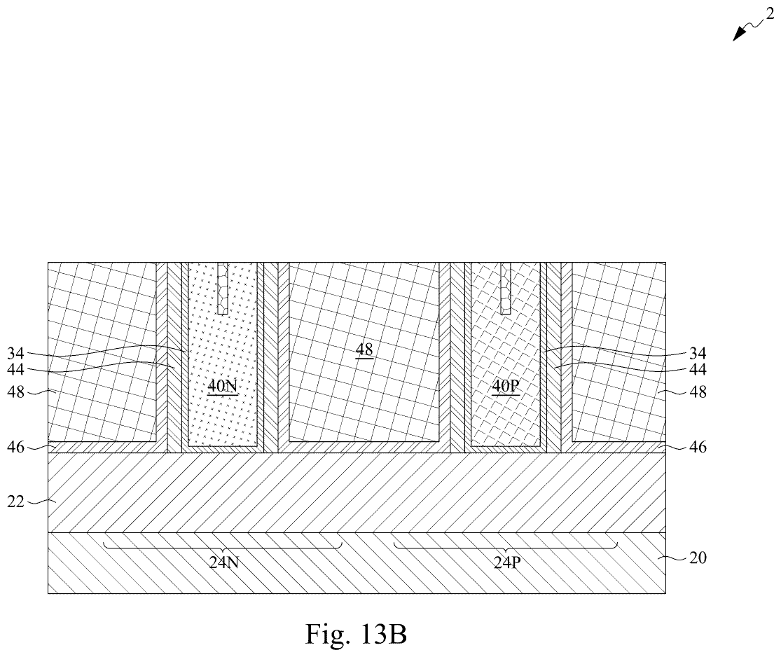

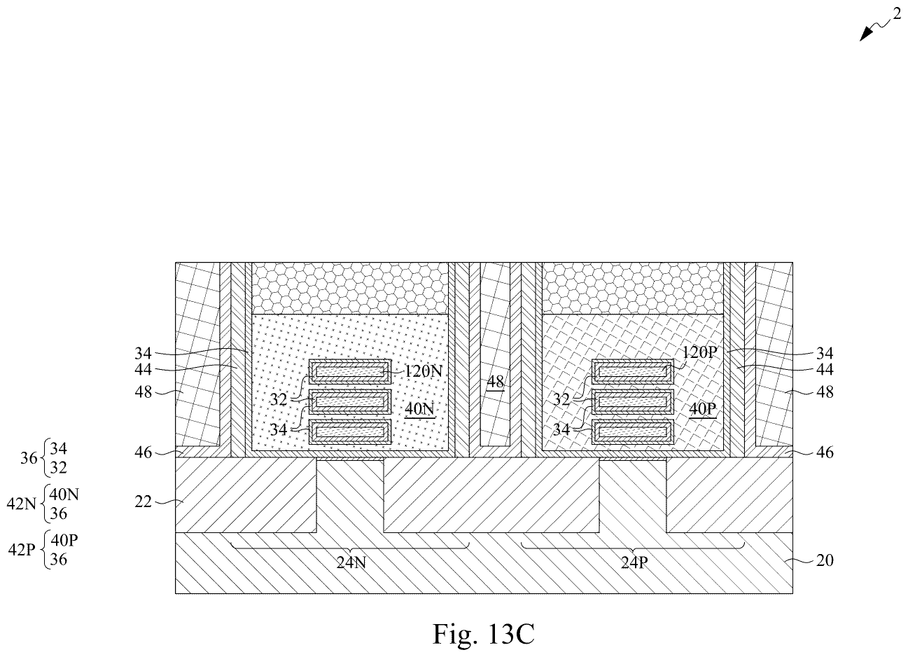

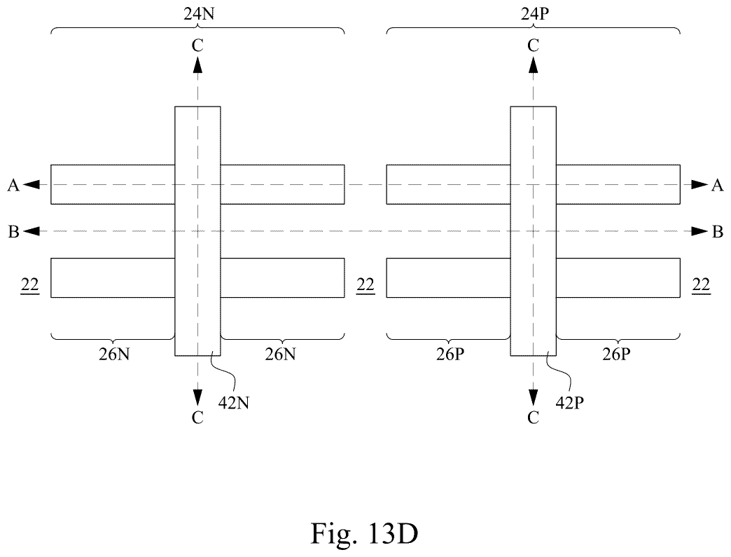

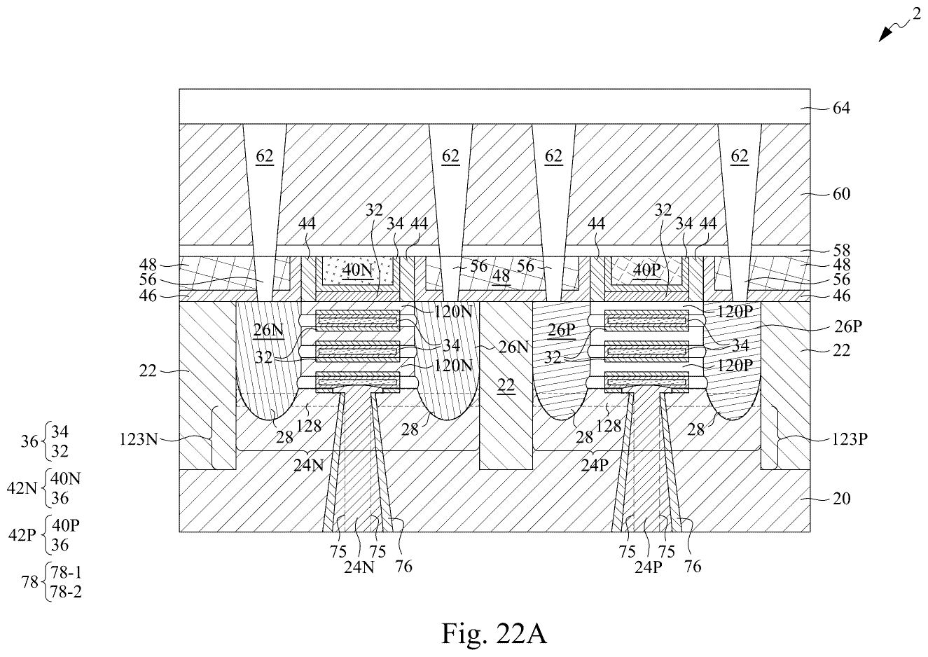

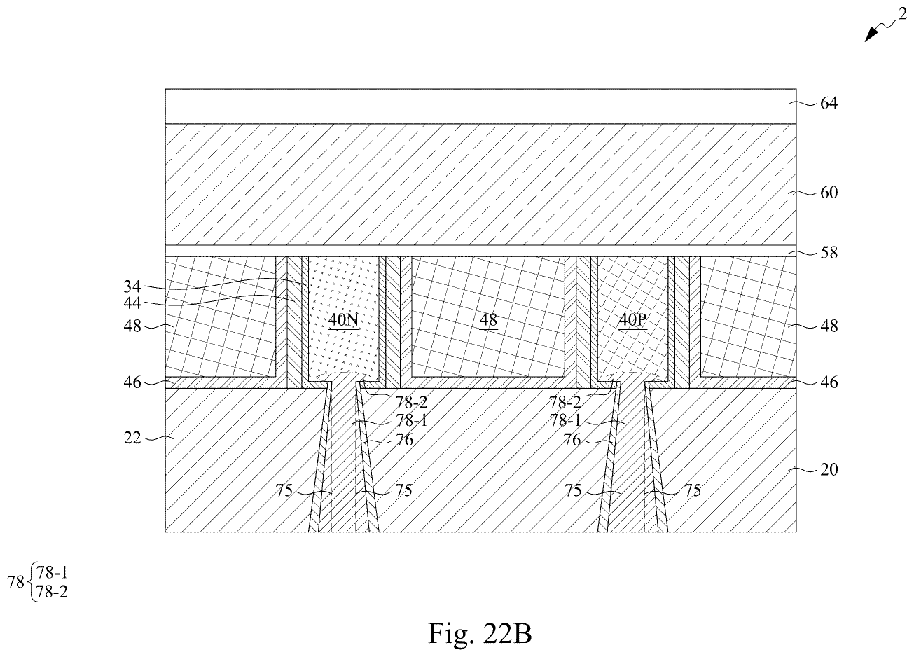

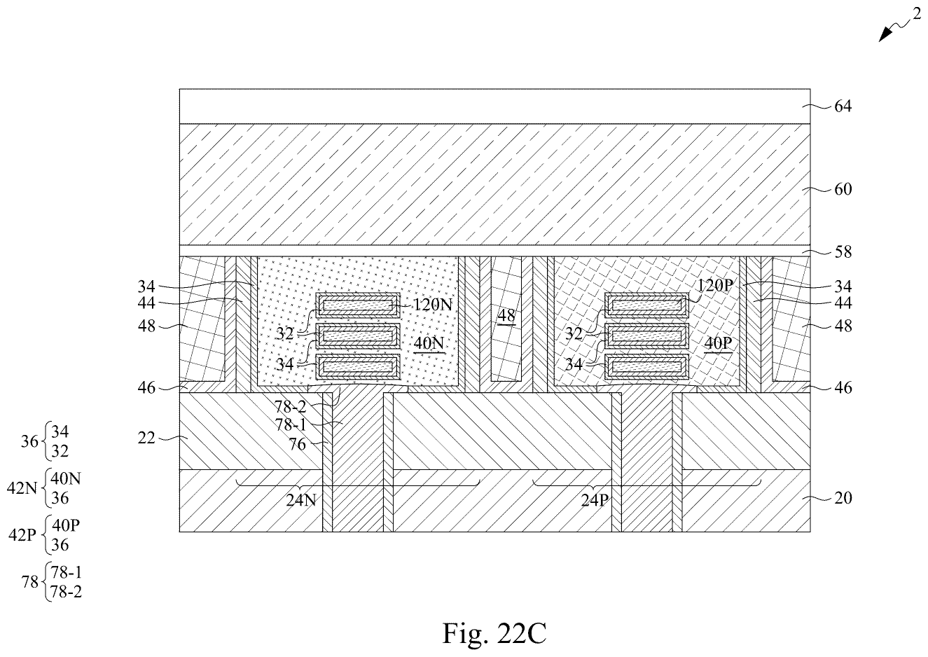

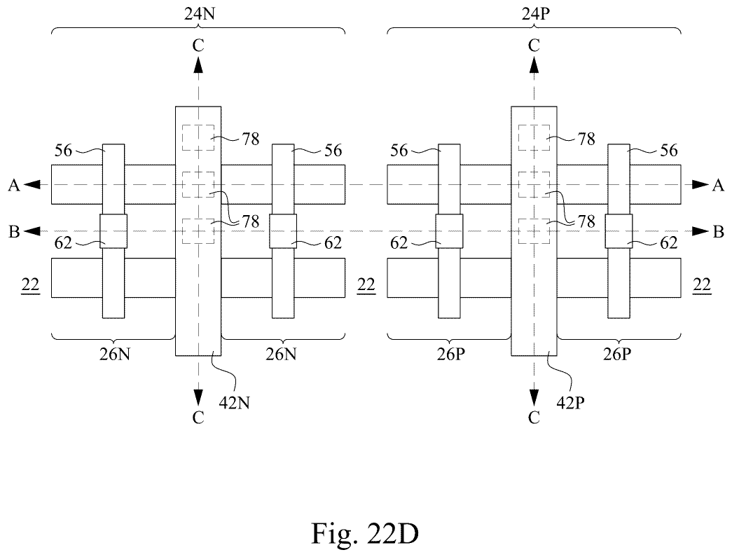

Dielectric regions 28 and dielectric layers 128 are also illustrated in the structure shown in FIG. 22A. For clarity of viewing, dielectric regions 28 and dielectric layers 128 are not illustrated in FIGS. 13A, 13B, 13C, 13D through FIG. 21, while dielectric layers 28 and 128 may also be formed in these figures.

FIGS. 13A, 13B, 13C, and 13D illustrate the views in the planarization process to remove the portions of gate electrode layers 40 and high-k dielectric layer 34, hence forming gate electrodes 40N and 40P and gate stacks 42N and 42P.

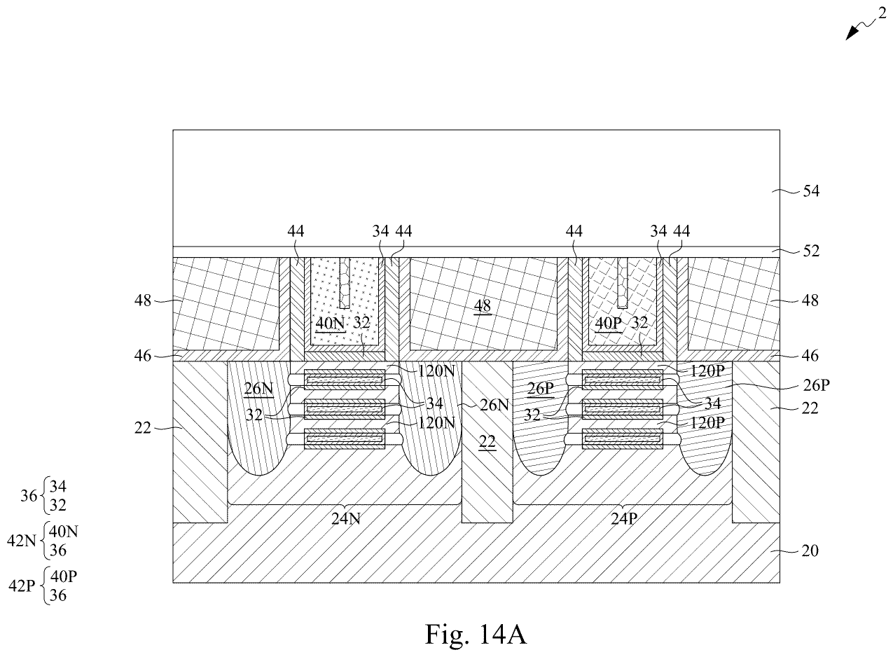

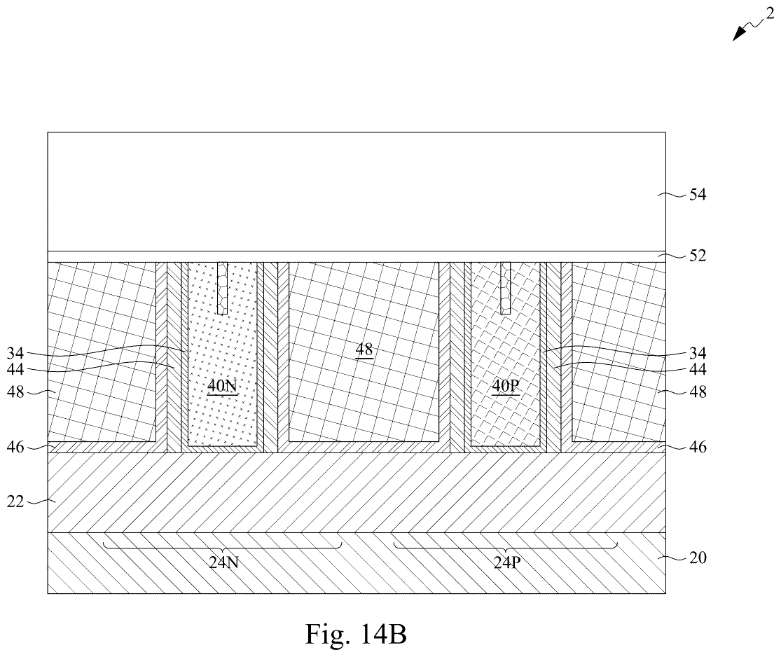

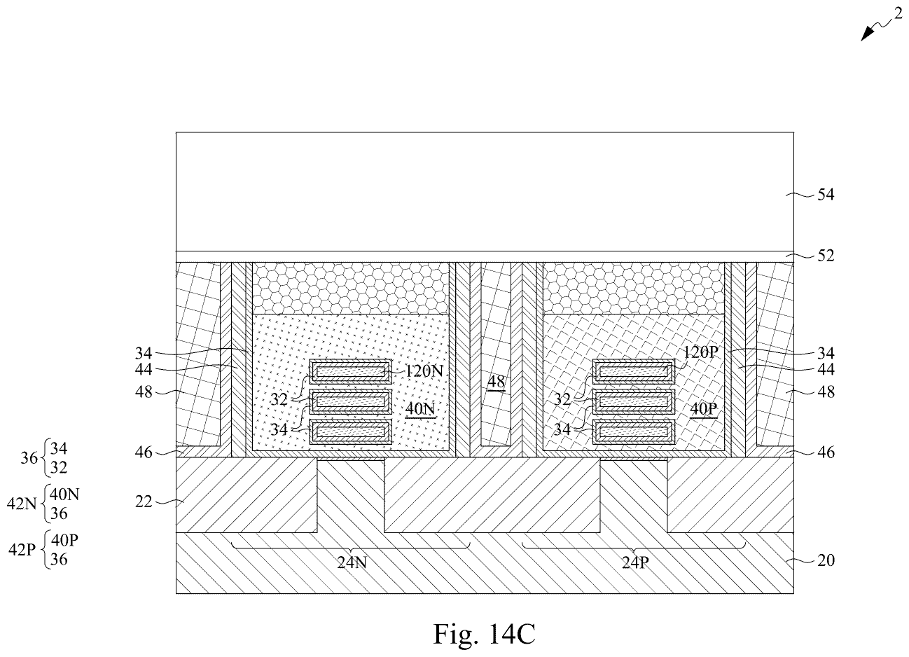

Next, referring to FIGS. 14A, 14B, and 14C, ESL 52 and ILD 54 are formed. The details of the materials, the structures, and the formation processes of ESL 52 and ILD 54 may be essentially the same as discussed referring to the preceding embodiments, and are not repeated herein. ESL 52 and ILD 54 may also be sacrificial layers that are removed in subsequent processes.

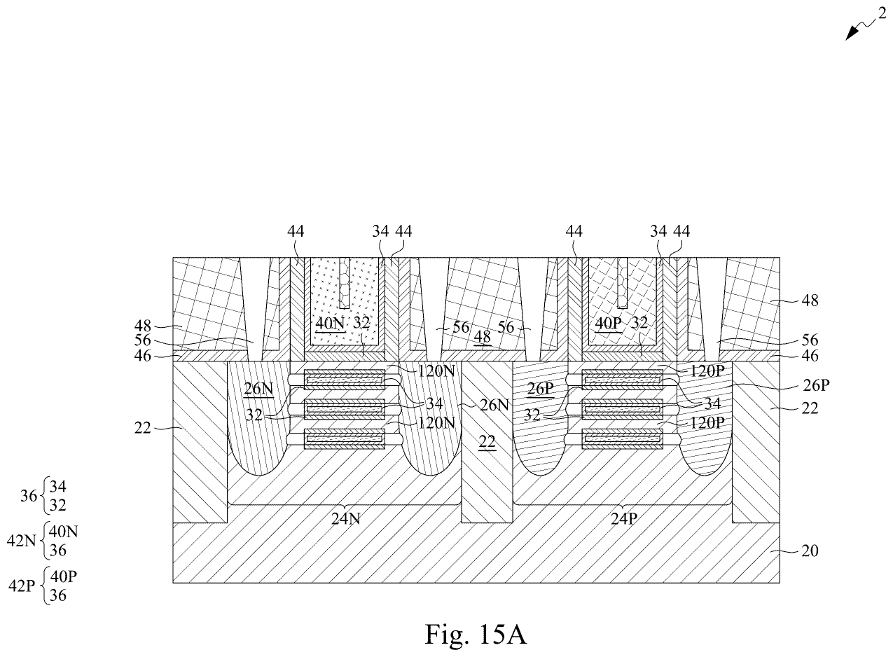

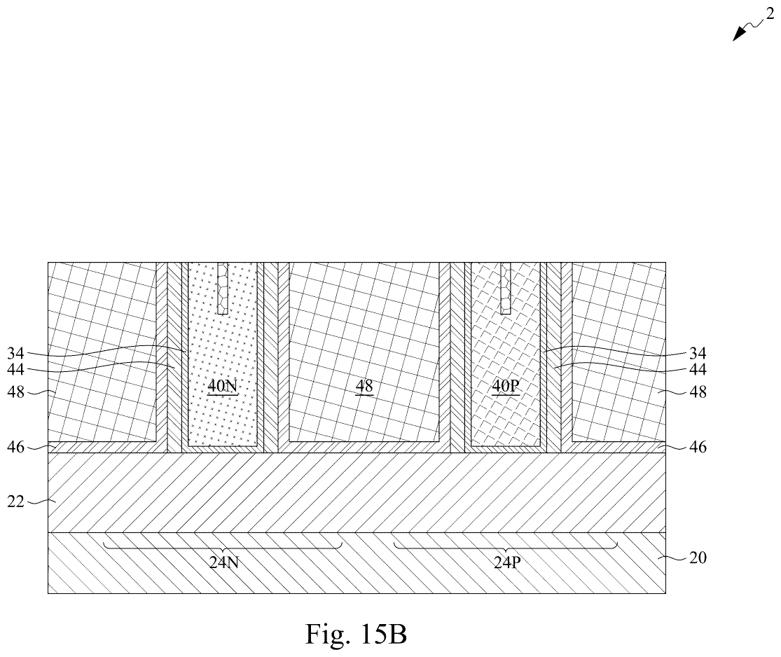

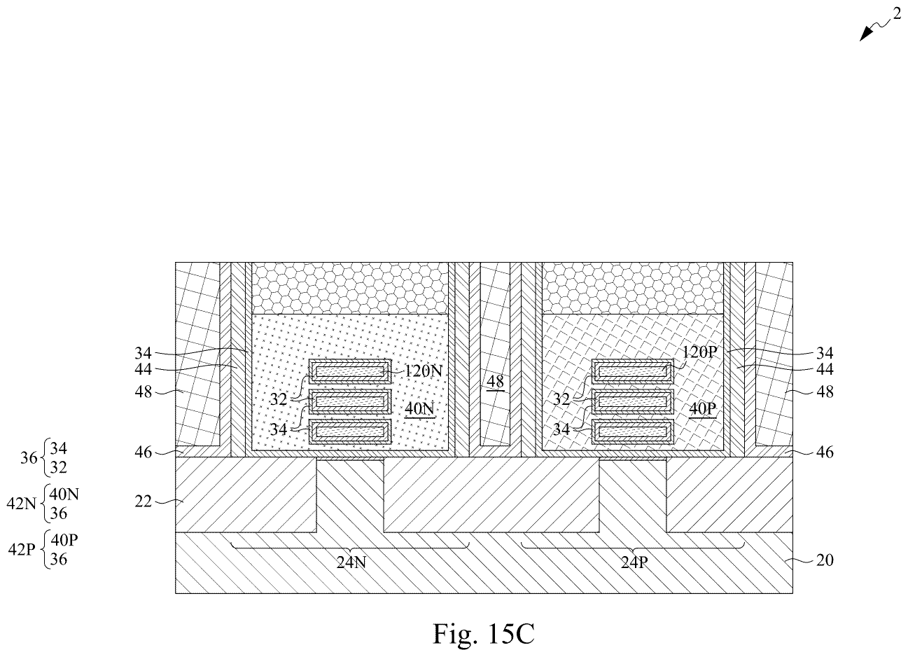

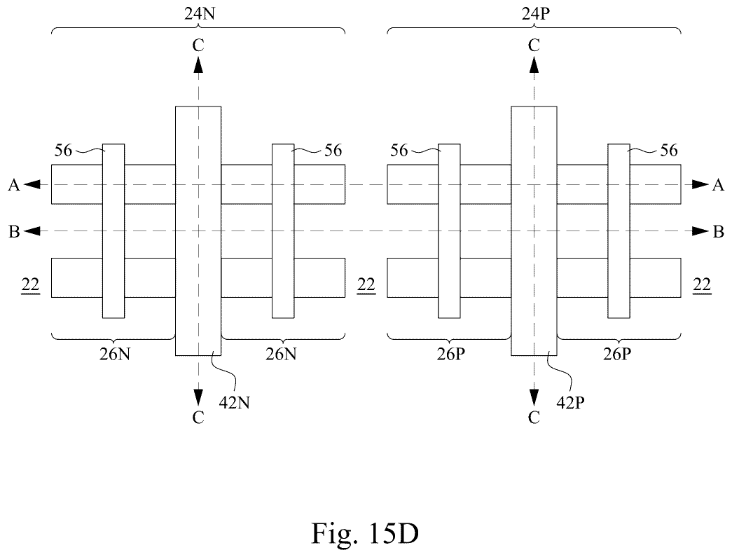

FIGS. 15A, 15B, 15C, and 15D illustrate the formation of source/drain contact plugs 56. Source/drain silicide layers (not shown) are also formed between source/drain contact plugs 56 and source/drain regions 26N and 26P. The details of the materials, the structures, and the formation processes of source/drain contact plugs 56 may be essentially the same as discussed referring to the preceding embodiments, and are not repeated herein. Again, while source/drain contact plugs 56 are not illustrated in FIG. 15B, source/drain contact plugs 56 may or may not extend into the cross-section of FIG. 15B.

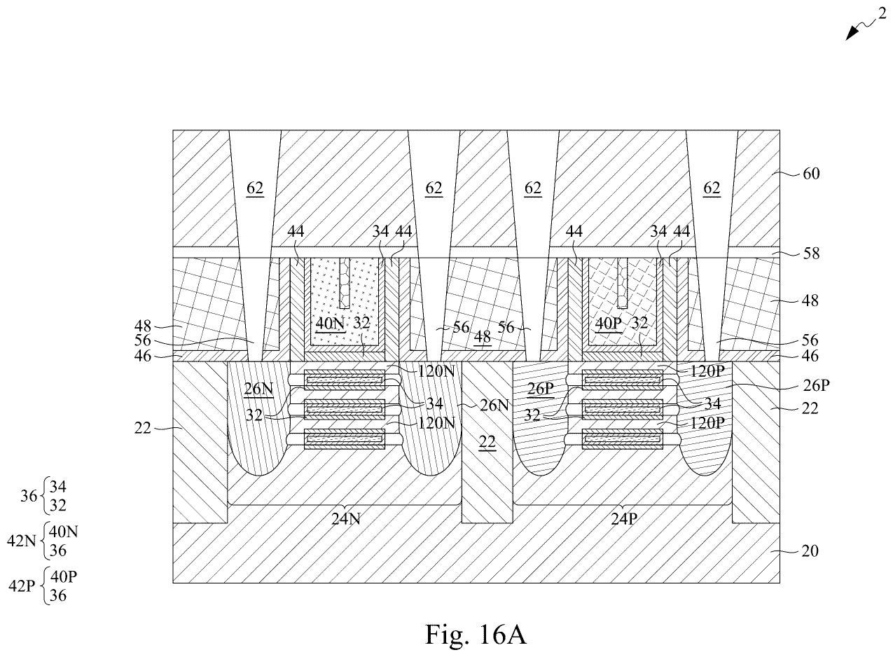

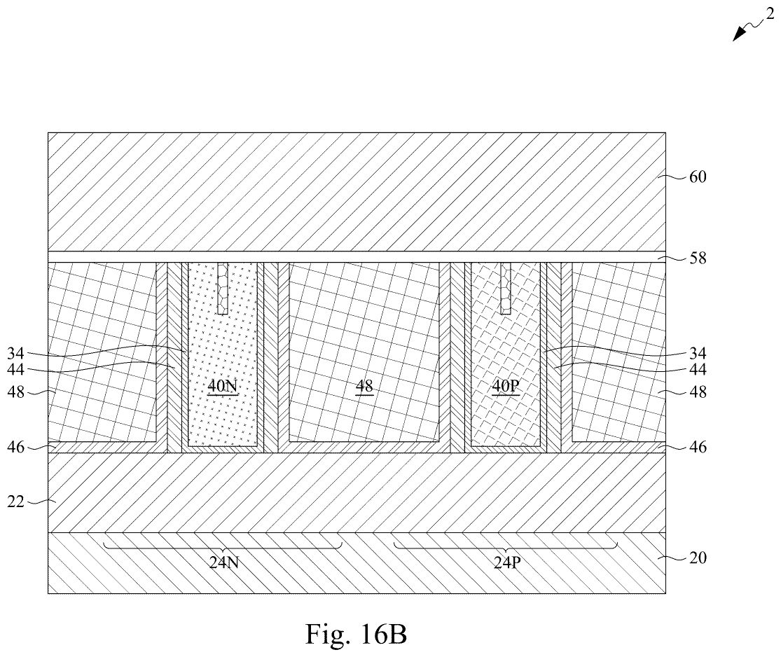

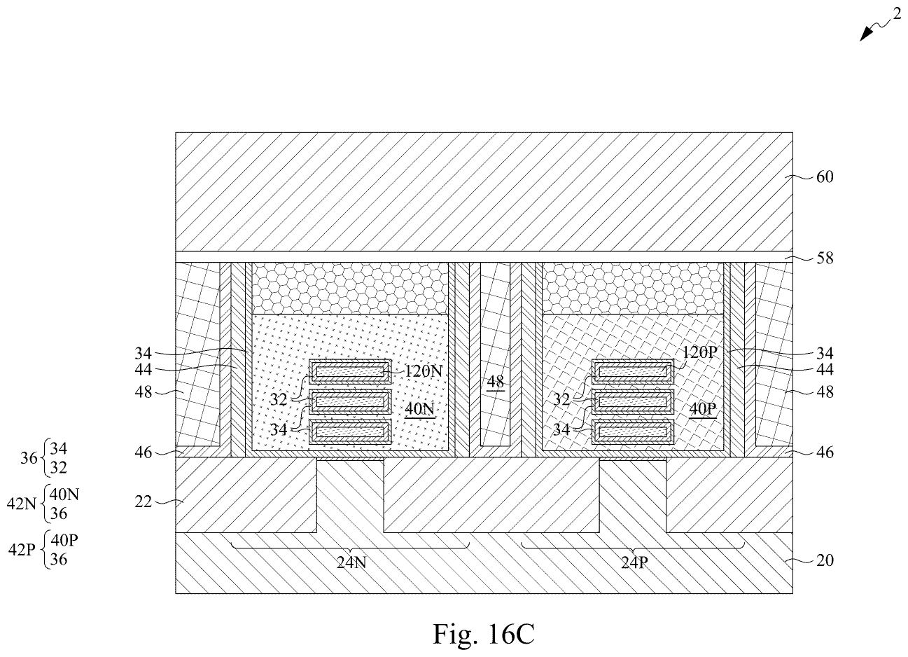

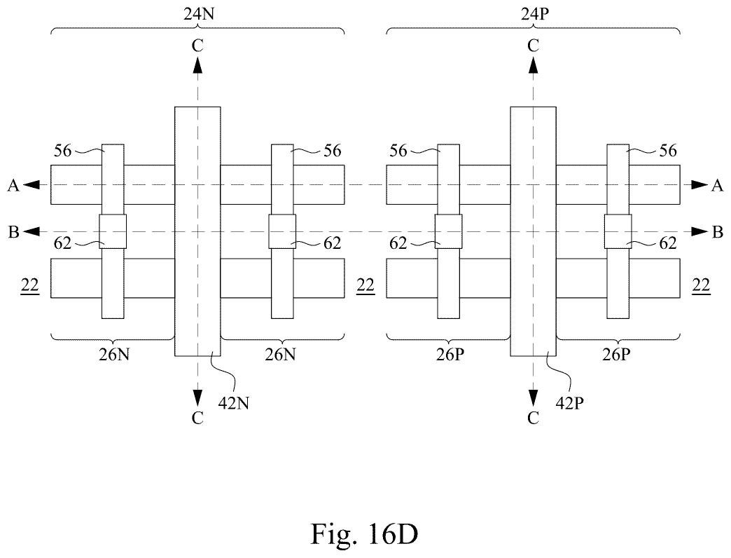

FIGS. 16A, 16B, and 16C illustrate the formation ESL 58, ILD 60, and conductive features 62. The details of the materials, the structures, and the formation processes of conductive features 62 may be essentially the same as discussed referring to the preceding embodiments, and are not repeated herein.

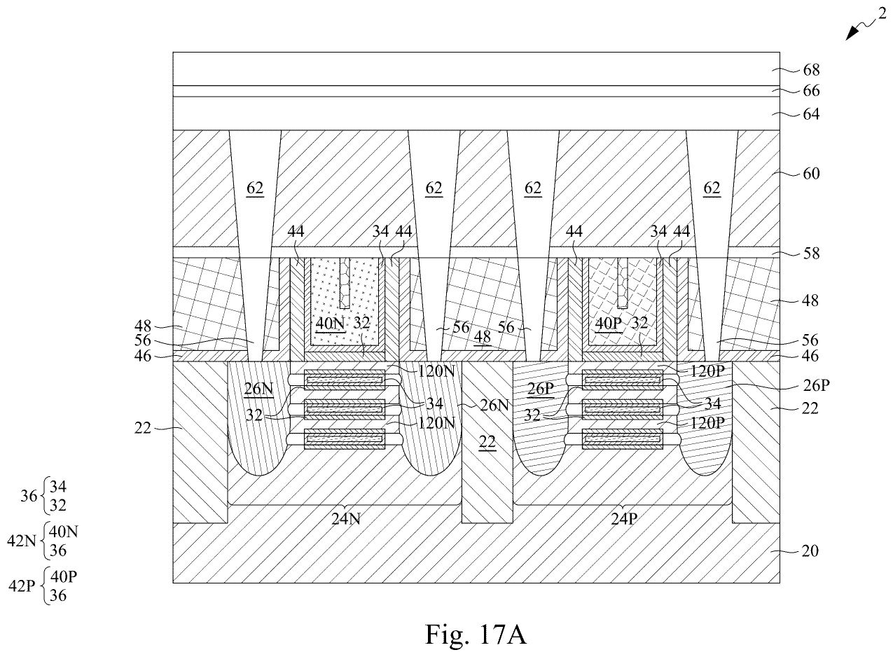

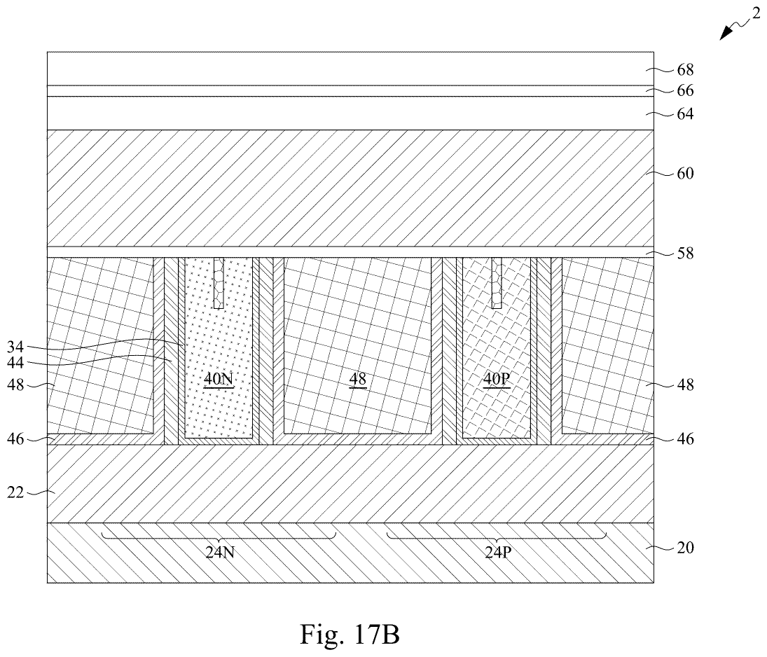

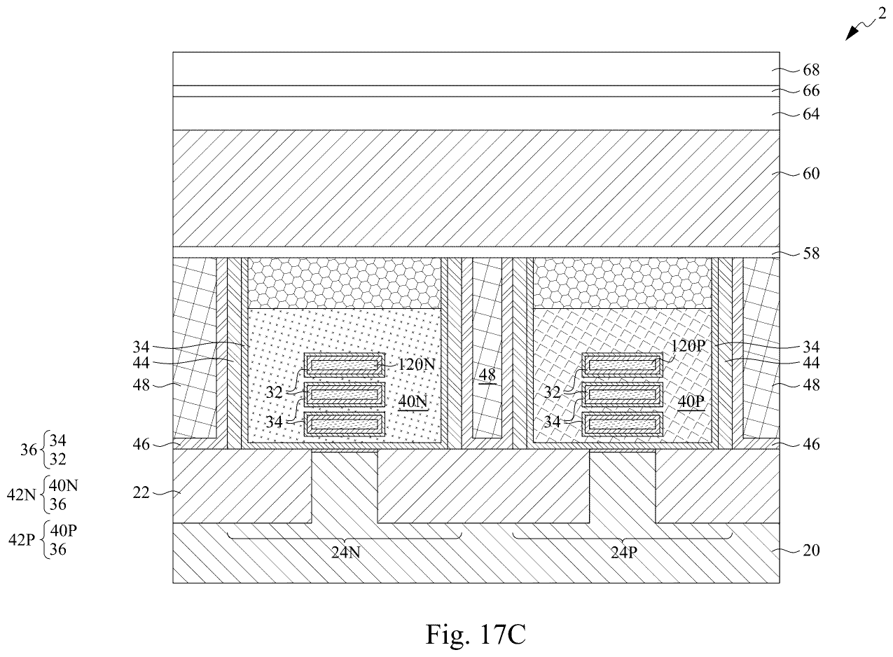

FIGS. 17A, 17B, and 17C illustrate the formation of interconnect structure 64 overlying n-type transistor 24N and p-type transistor 24P, Next, carrier 68 is attached to wafer 2. The attachment may be performed through release film 66 or through fusion bonding. The details of the materials, the structures, and the formation processes of these features may be essentially the same as discussed referring to the preceding embodiments, and are not repeated herein.

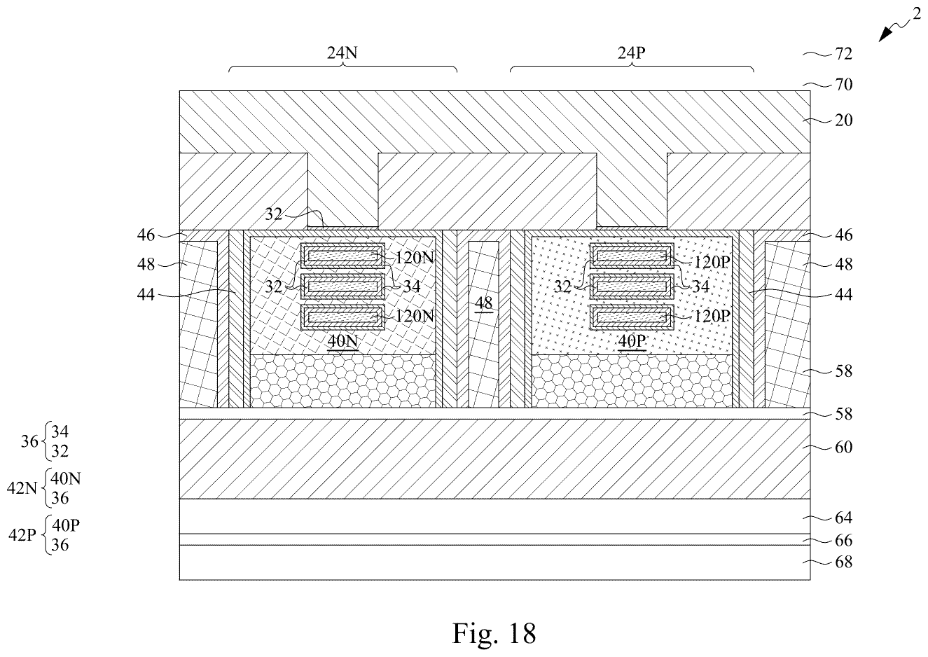

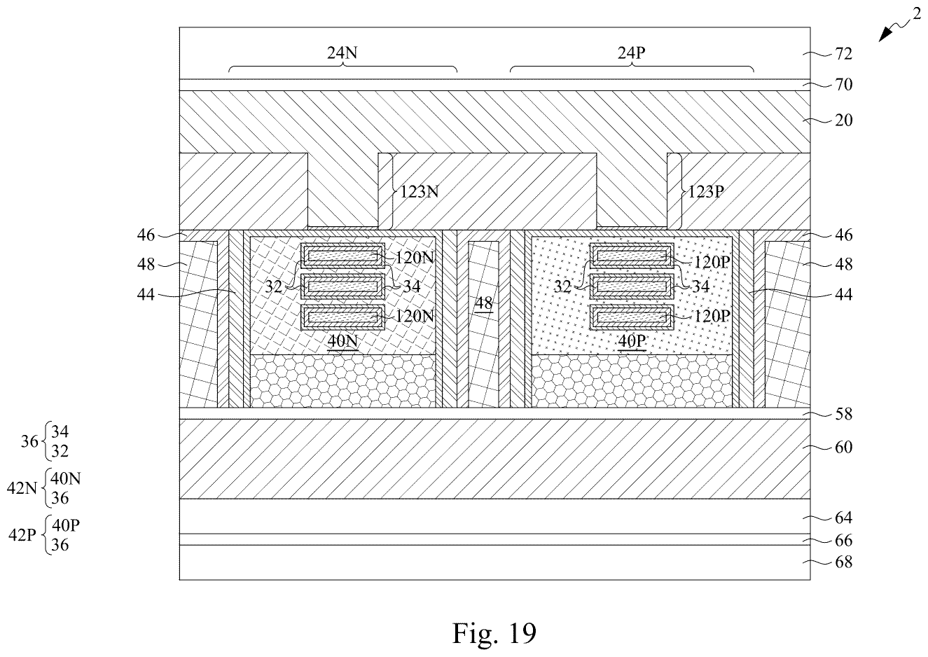

FIG. 18 illustrates the flipped wafer 2 in accordance with some embodiments. Next, as shown in FIG. 19, etch stop layer 70 and dielectric layer 72 are formed.

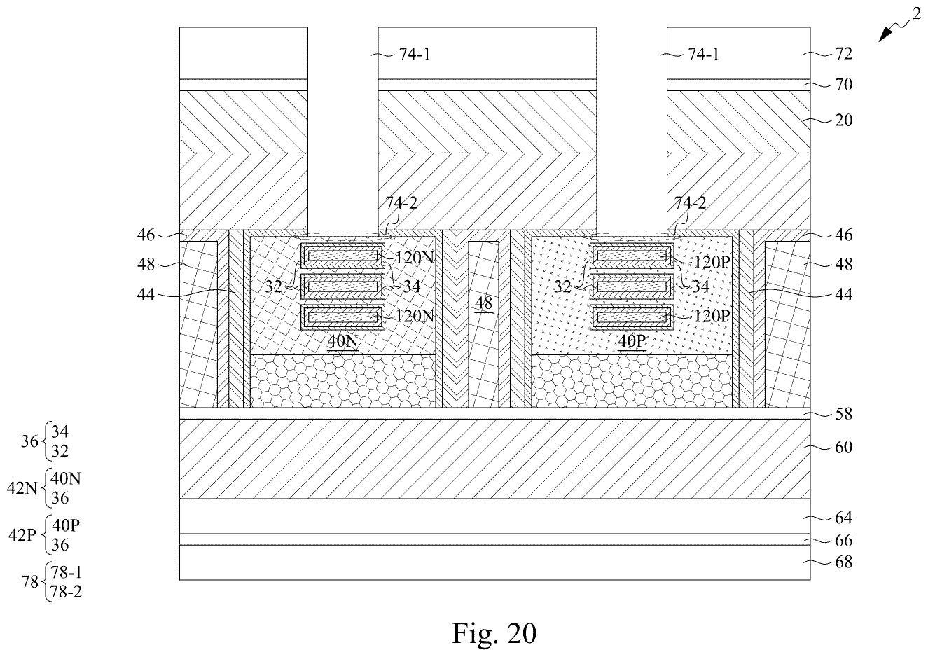

FIG. 20 illustrates the formation of contact openings 74. In accordance with some embodiments, the etching comprises etching bulk substrate 20 and removing the semiconductor strips 123N and 123P (FIG. 19). The resulting portions 74-1 of contact openings 74 thus may have vertical-and-straight edges in the cross-section in FIG. 20. In other cross-sections, for example, the vertical cross-section perpendicular to the cross-section of FIG. 20, contact openings 74 may have a funnel shape, as shown in FIGS. 22A and 22B.

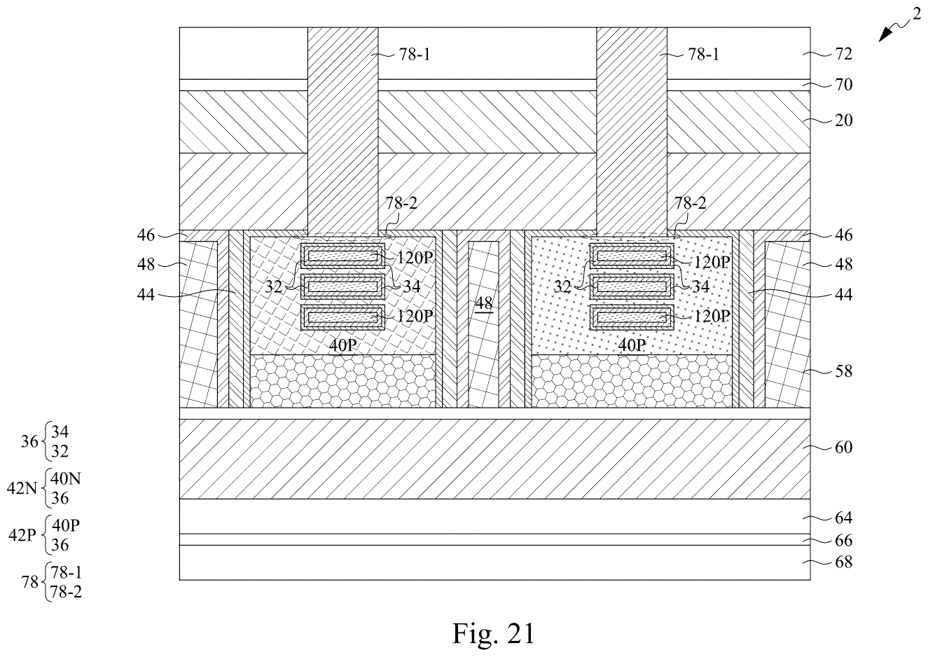

In addition, the formation of contact openings 74 may (or may not) comprise over-etching to form expansion portions 74-2 in gate electrodes 40N and 40P. The details in the formation of the expansion portion 74-2 has been discussed in detail in the preceding embodiments, and thus are not repeated herein. FIG. 21 illustrates the formation of dielectric isolation layers 76 and backside contact plugs 78, which comprise portions 78-1, and may or may not comprise expansion portions 78-2.

In subsequent processes, carrier 68 is detached from wafer 2, and wafer 2 is flipped upside down. FIGS. 22A, 22B, 22C, and 22D illustrate the respective transistors 24N and 24P and the backside contact plugs 78 in accordance with some embodiments.

It is appreciated that FIGS. 22A and 22C illustrate a first embodiment in which the backside contact plugs 78 are directly underlying nanostructures 120N and 120P, while FIG. 22B illustrates a second embodiment in which the backside contact plugs 78 penetrate through STI regions 22. FIG. 22D illustrates the possible positions of backside contact plugs 78 as shown in FIG. 22A/22C and 22B. In accordance with some embodiments, both of the backside contact plugs 78 in FIG. 22A/22C and 22B may be formed to reduce resistance. In accordance with alternative embodiments, either the backside contact plugs 78 in FIG. 22A/22C or the backside contact plugs 78 in FIG. 22B may be adopted.

In accordance with various embodiments, backside contact plugs 78 may or may not include expansion portions, which are formed by over-etching. Backside contact plugs 78 may have funnel shapes as shown in FIG. 22A, or may have vertical-and-straight edges, as shown by dashed lines 75 in FIG. 22A. There may be, or may not be, dielectric regions 28 directly underlying source/drain regions 26N and 26P. There may be, or may not be, dielectric layers 128 directly underlying nanostructures 120N and 120P, which form the channel regions of the respective transistors. All possible combinations of these embodiments are in the scope of the present disclosure.

In accordance with some illustrated embodiments, gate contact plugs may be formed on the backside of transistors, while the source/drain contact plugs are formed on the front side of the transistors. In accordance with alternative embodiments, gate contact plugs may be formed on the front side of transistors, and the source/drain contact plugs may be formed on the backside of the transistors.

In accordance with yet alternative embodiments, the gate contact plugs of a first transistor are formed on a first side of the transistors, and the gate contact plugs of a second transistor neighboring the first transistor are formed on a second side of the transistors opposite to the first side. The source/drain contact plugs of the first transistor, conversely, are formed on the second side, and the source/drain contact plugs of the second transistor are formed on the first side.

The embodiments of the present disclosure have some advantageous features. By forming source/drain contact plugs on the front side of transistors, and forming gate contact plugs on the backside of the transistors, the pitches of neighboring contact plugs may be increased, and the leakage and the possibility of electrical shorting are also reduced.

In accordance with some embodiments of the present disclosure, a method comprises forming a transistor as a part of a wafer, the transistor comprising a semiconductor channel; a gate stack comprising a gate dielectric over the semiconductor channel; and a gate electrode over the gate dielectric; and a source/drain region aside of, and joined to, an end of the semiconductor channel; forming a source/drain contact plug over and electrically coupling to the source/drain region; performing an etching process from a backside of the wafer to form a gate contact opening, wherein the gate dielectric is etched-through, and wherein the gate electrode is exposed to the gate contact opening; and forming a backside gate contact plug in the gate contact opening.

In an embodiment, the transistor is a Fin Field-Effect Transistor (FinFET) comprising a semiconductor fin as the semiconductor channel, and wherein the backside gate contact plug is aside of the semiconductor fin. In an embodiment, the backside gate contact plug penetrates through a shallow trench isolation region. In an embodiment, the backside gate contact plug further penetrates through a bulk semiconductor substrate that is underlying and contacting the shallow trench isolation region.

In an embodiment, the transistor is a nanostructure transistor comprising a semiconductor nanostructure as a part of the semiconductor channel, and wherein the gate stack comprises a part encircling the semiconductor nanostructure. In an embodiment, the backside gate contact plug is overlapped by the semiconductor nanostructure. In an embodiment, the semiconductor nanostructure overlaps a dielectric layer, and the backside gate contact plug penetrates through the dielectric layer and a semiconductor region underlying the dielectric layer. In an embodiment, the source/drain region overlaps and contacts a dielectric isolation region.

In an embodiment, the etching process comprises performing a first etching process to etch-through a feature underlying the gate stack; and performing a second etching process to widen a portion of the gate contact opening in the gate stack. In an embodiment, the second etching process is more isotropic than the first etching process. In an embodiment, the feature is selected from the group consisting of a shallow trench isolation region, a semiconductor region, and a combination thereof. In an embodiment, the backside gate contact plug has a funnel shape.

In accordance with some embodiments of the present disclosure, a method comprises forming a plurality of shallow trench isolation regions over a bulk portion of a semiconductor substrate; forming a nanostructure transistor comprising a plurality of semiconductor nanostructures over a semiconductor strip, wherein the semiconductor strip is between two of the plurality of shallow trench isolation regions; a gate stack comprising intermediate portions between the plurality of semiconductor nanostructures, wherein the intermediate portions further comprise a gate dielectric and a gate electrode contacting the gate dielectric; and a source/drain region aside of and connecting to the plurality of semiconductor nanostructures; forming a source/drain contact plug electrically connecting to the source/drain region; and forming a gate contact plug electrically connecting to the gate electrode, wherein the source/drain contact plug and the gate contact plug are on opposite sides of the nanostructure transistor.

In an embodiment, the source/drain contact plug is formed on a front side of the nanostructure transistor, and the gate contact plug is formed on a backside of the nanostructure transistor. In an embodiment, the gate contact plug comprises a first portion outside of the gate stack; and a second portion in the gate stack, wherein the second portion is wider than the first portion.

In accordance with some embodiments of the present disclosure, a structure comprises a bulk semiconductor substrate; a semiconductor strip over the bulk semiconductor substrate; a first shallow trench isolation region and a second shallow trench isolation region contacting opposing sidewalls of the semiconductor strip; a plurality of semiconductor nanostructures overlapping the semiconductor strip; a gate stack comprising portions between the plurality of semiconductor nanostructures, wherein the gate stack comprises a gate dielectric and a gate electrode contacting the gate dielectric; a source/drain region aside of and connecting to the plurality of semiconductor nanostructures; a source/drain contact plug overlying and electrically connecting to the source/drain region; and a gate contact plug underlying an dielectrically connecting to the gate electrode.

In an embodiment, the gate contact plug comprises a first portion in the gate stack; and a second portion underlying the first portion, wherein the first portion is wider than the second portion. In an embodiment, the structure further comprises a dielectric layer overlapped by the plurality of semiconductor nanostructures and overlapping the semiconductor strip, wherein the gate contact plug penetrates through the dielectric layer.

In an embodiment, the structure further comprises a dielectric region overlapped by the source/drain region and overlapping the semiconductor strip. In an embodiment, in a first cross-sectional cutting through the source/drain region and the plurality of semiconductor nanostructures, the gate contact plug has a funnel shape, and in a second cross-sectional perpendicular to the first cross-section, the gate contact plug has vertical-and-straight edges.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a transistor as a part of a wafer, the transistor comprising:
a semiconductor channel;
a gate stack comprising:
a gate dielectric over the semiconductor channel; and
a gate electrode over the gate dielectric; and
a source/drain region aside of, and joined to, an end of the semiconductor channel;
forming a source/drain contact plug over and electrically coupling to the source/drain region;
performing an etching process from a backside of the wafer to form a gate contact opening, wherein the gate dielectric is etched-through, and wherein the gate electrode is exposed to the gate contact opening; and
forming a backside gate contact plug in the gate contact opening.

2. The method of claim 1, wherein the transistor is a Fin Field-Effect Transistor (FinFET) comprising a semiconductor fin as the semiconductor channel, and wherein the backside gate contact plug is aside of the semiconductor fin.

3. The method of claim 2, wherein the backside gate contact plug penetrates through a shallow trench isolation region.

4. The method of claim 3, wherein the backside gate contact plug further penetrates through a bulk semiconductor substrate that is underlying and contacting the shallow trench isolation region.

5. The method of claim 1, wherein the transistor is a nanostructure transistor comprising a semiconductor nanostructure as a part of the semiconductor channel, and wherein the gate stack comprises a part encircling the semiconductor nanostructure.

6. The method of claim 5, wherein the backside gate contact plug is overlapped by the semiconductor nanostructure.

7. The method of claim 5, wherein the semiconductor nanostructure overlaps a dielectric layer, and the backside gate contact plug penetrates through the dielectric layer and a semiconductor region underlying the dielectric layer.

8. The method of claim 5, wherein the source/drain region overlaps and contacts a dielectric isolation region.

9. The method of claim 1, wherein the etching process comprises:
performing a first etching process to etch-through a feature underlying the gate stack; and
performing a second etching process to widen a portion of the gate contact opening in the gate stack.

10. The method of claim 9, wherein the second etching process is more isotropic than the first etching process.

11. The method of claim 9, wherein the feature is selected from the group consisting of a shallow trench isolation region, a semiconductor region, and a combination thereof.

12. The method of claim 1, wherein the backside gate contact plug has a funnel shape.

13. A method comprising:
forming a plurality of shallow trench isolation regions over a bulk portion of a semiconductor substrate;
forming a nanostructure transistor comprising:
a plurality of semiconductor nanostructures over a semiconductor strip, wherein the semiconductor strip is between two of the plurality of shallow trench isolation regions;
a gate stack comprising intermediate portions between the plurality of semiconductor nanostructures, wherein the intermediate portions further comprise a gate dielectric and a gate electrode contacting the gate dielectric; and
a source/drain region aside of and connecting to the plurality of semiconductor nanostructures;
forming a source/drain contact plug electrically connecting to the source/drain region; and
forming a gate contact plug electrically connecting to the gate electrode, wherein the source/drain contact plug and the gate contact plug are on opposite sides of the nanostructure transistor.

14. The method of claim 13, wherein the source/drain contact plug is formed on a front side of the nanostructure transistor, and the gate contact plug is formed on a backside of the nanostructure transistor.

15. The method of claim 13, wherein the gate contact plug comprises:
a first portion outside of the gate stack; and
a second portion in the gate stack, wherein the second portion is wider than the first portion.

16. A structure comprising:
a bulk semiconductor substrate;
a semiconductor strip over the bulk semiconductor substrate;
a first shallow trench isolation region and a second shallow trench isolation region contacting opposing sidewalls of the semiconductor strip;
a plurality of semiconductor nanostructures overlapping the semiconductor strip;
a gate stack comprising portions between the plurality of semiconductor nanostructures, wherein the gate stack comprises a gate dielectric and a gate electrode contacting the gate dielectric;
a source/drain region aside of and connecting to the plurality of semiconductor nanostructures;
a source/drain contact plug overlying and electrically connecting to the source/drain region; and
a gate contact plug underlying an dielectrically connecting to the gate electrode.

17. The structure of claim 16, wherein the gate contact plug comprises:
a first portion in the gate stack; and
a second portion underlying the first portion, wherein the first portion is wider than the second portion.

18. The structure of claim 16 further comprising a dielectric layer overlapped by the plurality of semiconductor nanostructures and overlapping the semiconductor strip, wherein the gate contact plug penetrates through the dielectric layer.

19. The structure of claim 16 further comprising a dielectric region overlapped by the source/drain region and overlapping the semiconductor strip.

20. The structure of claim 16, wherein in a first cross-sectional cutting through the source/drain region and the plurality of semiconductor nanostructures, the gate contact plug has a funnel shape, and in a second cross-sectional perpendicular to the first cross-section, the gate contact plug has vertical-and-straight edges.
